(19) United States
(12) Patent Application Publication
(10) Pub. No.: US 2026/0068298 A1
(43) Pub. Date: Mar. 5, 2026

(54) INTEGRATED CIRCUIT DEVICE

(71) Applicant: Samsung Electronics Co., Ltd., Suwon-si (KR)

(72) Inventors: Junggil Yang, Suwon-si (KR); Dongwon Kim, Suwon-si (KR)

(21) Appl. No.: 19/290,529

(22) Filed: Aug. 5, 2025

(30) Foreign Application Priority Data
Sep. 4, 2024 (KR) 10-2024-0120320
Dec. 6, 2024 (KR) 10-2024-0180427

(51) Int. Cl. H10D 84/83; H10D 30/00; H10D 30/01; H10D 30/43; H10D 62/10; H10D 62/13; H10D 64/23; H10D 64/68; H10D 84/01

(52) U.S. Cl. CPC H10D 84/832; H10D 30/43; H10D 30/502; H10D 62/102; H10D 62/116; H10D 62/121; H10D 62/151; H10D 64/256; H10D 64/685; H10D 30/014; H10D 30/0191; H10D 84/0149; H10D 84/0151; H10D 84/8312

(57) ABSTRACT

An integrated circuit device includes an active region extending lengthwise in a first direction on a substrate, a gate structure including a gate line, a high dielectric layer, and an interface dielectric layer, which extend lengthwise in a second direction perpendicular to the first horizontal direction on the active region, a nanosheet arranged on a fin upper surface of the active region and contacting the gate structure, a source/drain region arranged on the active region and contacting the nanosheet, and under the source/drain region in a direction perpendicular to both the first direction and the second direction, a lower insulating spacer arranged in a source/drain recess extending from the fin upper surface of the active region, wherein the interface dielectric layer includes a first portion extending on the nanosheet, and a second portion extending on the source/drain region, and wherein a first thickness of the first portion is different from a second thickness of the second portion.

### CROSS-REFERENCE TO RELATED APPLICATIONS

This application is based on and claims priority under 35 U.S.C. § 119 to Korean Patent Application Nos. 10-2024-0120320, filed on Sep. 4, 2024, and 10-2024-0180427, filed on Dec. 6, 2024, in the Korean Intellectual Property office, the disclosures of which are incorporated by reference herein in their entireties.

### BACKGROUND

The inventive concept relates to an integrated circuit device, and more particularly, to an integrated circuit device including a field-effect transistor.

As down-scaling of integrated circuit devices progresses rapidly, it may be necessary to secure operational accuracy in integrated circuit devices due to increased leakage current as well as high operational speed. Accordingly, various research has been conducted to provide an integrated circuit device having a structure capable of reducing leakage current and improving reliability.

### SUMMARY

The inventive concept provides an integrated circuit device having a structure capable of improving reliability by reducing leakage current of an electric-field transistor including a nanosheet channel region.

However, the issues to be solved by the inventive concept are not limited to those described above, and other issues may be clearly understood by those of skill in the art from the following descriptions.

According to an aspect of the inventive concept, there is provided an integrated circuit device including an active region extending lengthwise in a first direction on a substrate, a gate structure including a gate line, a high dielectric layer, and an interface dielectric layer, which extend long in a second direction perpendicular to the first direction on the active region, a nanosheet arranged on a fin upper surface of the active region and contacting the gate structure, a source/drain region arranged on the active region and contacting the nanosheet, and under the source/drain region in a third direction perpendicular to both the first direction and the second direction, a lower insulating spacer arranged in a source/drain recess extending from the fin upper surface of the active region, wherein the interface dielectric layer includes a first portion extending on the nanosheet, and a second portion extending on the source/drain region, and wherein a first thickness of the first portion is different from a second thickness of the second portion.

According to another aspect of the inventive concept, there is provided an integrated circuit device including an active region extending lengthwise in a first direction on a substrate, a gate structure including a gate line, a high dielectric layer, and an interface dielectric layer, which extend long in a second direction perpendicular to the first direction on the active region, a nanosheet arranged on a frontside surface of the active region, and at least partially surrounded by the gate structure, a source/drain region arranged on the active region and contacting the nanosheet, a lower insulating spacer between the source/drain region and the substrate, and a backside contact structure that extends through the active region and the lower insulating spacer from a backside surface facing the frontside surface of the active region, and is connected to the source/drain region, wherein the interface dielectric layer includes a first portion extending on the nanosheet, and
a second portion extending on the source/drain region, and wherein a first thickness of the first portion is different from a second thickness of the second portion.

According to another aspect of the inventive concept, there is provided an integrated circuit device including a plurality of active regions extending lengthwise in a first direction on a substrate, and being apart from each other in a second direction crossing the first direction, a device separation layer on sidewalls of each of the plurality of active regions, a gate structure including a gate line, a high dielectric layer, and an interface dielectric layer extending lengthwise in the second direction on the plurality of active regions, a plurality of nanosheets arranged on a fin upper surface of each of the plurality of active regions, each of the plurality of nanosheets including at least one nanosheet, and the plurality of active regions at least partially surrounded by the gate line, a source/drain region arranged on the plurality of source/drain regions, and arranged between the plurality of nanosheet stacks, and under the source/drain region in a third direction perpendicular to both the first direction and the second direction, a lower insulating spacer arranged in a source/drain recess extending from the fin upper surface of the active region, wherein the interface dielectric layer includes a first portion extending on the nanosheet, and a second portion extending on the source/drain region, and wherein a first thickness of the first portion is less than a second thickness of the second portion.

### BRIEF DESCRIPTION OF THE DRAWINGS

Embodiments will be more clearly understood from the following detailed description taken in conjunction with the accompanying drawings in which:

FIG. 1 is a layout of an integrated circuit device according to an embodiment;

FIG. 2 is a cross-sectional view of the integrated circuit device taken along line X1-X1 in FIG. 1;

FIGS. 3A, 3B, and 3C are enlarged views of a region EX1 in FIG. 2;

FIG. 4 is an enlarged view of a region EX2 in FIG. 2;

FIG. 5 is a cross-sectional view of the integrated circuit device taken along line Y1-Y1 in FIG. 1;

FIG. 6 is a diagram of a region of the integrated circuit device corresponding to a cross section taken along line X1-X1 in FIG. 1, and is a cross-sectional view illustrating an integrated circuit device according to another embodiment;

FIGS. 7A, 7B, and 7C are enlarged views of a region EX3 in FIG. 6;

FIG. 8 is a layout of an integrated circuit device according to another embodiment;

FIG. 9 is a cross-sectional view of the integrated circuit device taken along line X1-X1 in FIG. 8;

FIG. 10 is a cross-sectional view of the integrated circuit device taken along line Y1-Y1 in FIG. 8;

FIG. 11 is a cross-sectional view of the integrated circuit device taken along line Y2-Y2 in FIG. 8;

FIGS. 12 through 24 are cross-sectional views illustrating a method of manufacturing an integrated circuit device, according to embodiments;

FIGS. 25A, 25B, 25C, and 25D are cross-sectional views illustrating a method of manufacturing an integrated circuit device, according to embodiments; and

FIGS. 27 through 30 are cross-sectional views illustrating a method of manufacturing an integrated circuit device, according to embodiments.

### DETAILED DESCRIPTION OF THE EMBODIMENTS

Hereinafter, embodiments of the inventive concept are described in detail with reference to the accompanying drawings. Identical reference numerals are used for the same constituent elements in the drawings, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

In the inventive concept, a horizontal direction may include a first horizontal direction (X direction) or first direction and a second horizontal direction (Y direction) or second direction that cross each other. A third direction vertically intersecting the first horizontal direction (X direction) and the second horizontal direction (Y direction) may be referred to as a vertical direction (Z direction). In the inventive concept, a vertical level may be referred to as a height level according to the vertical direction (Z direction) of any configuration.

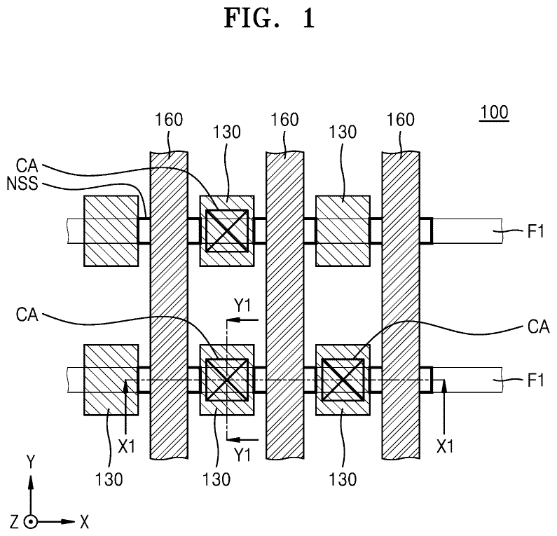

FIG. 1 is a layout of an integrated circuit device 100 according to an embodiment.

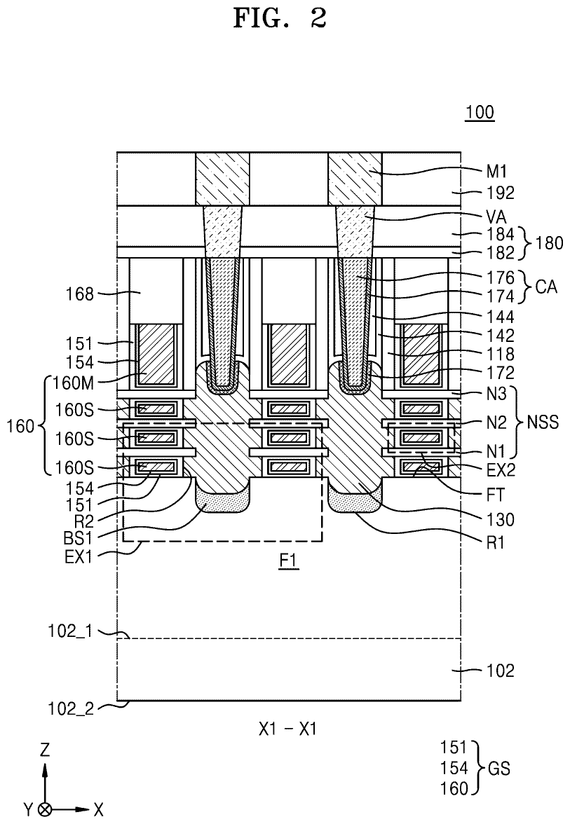

FIG. 2 is a cross-sectional view of the integrated circuit device 100 taken along line X1-X1 in FIG. 1.

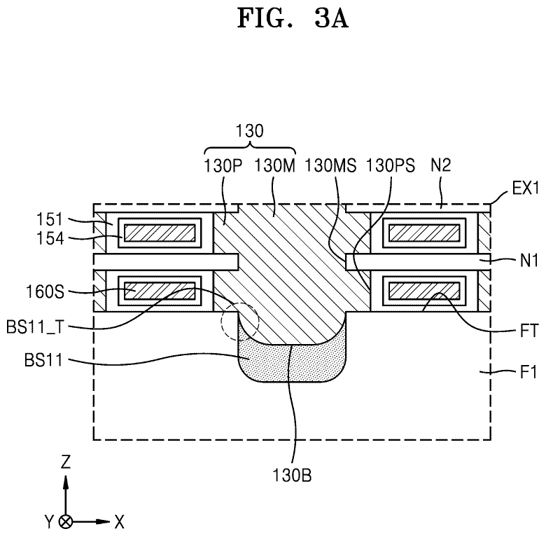

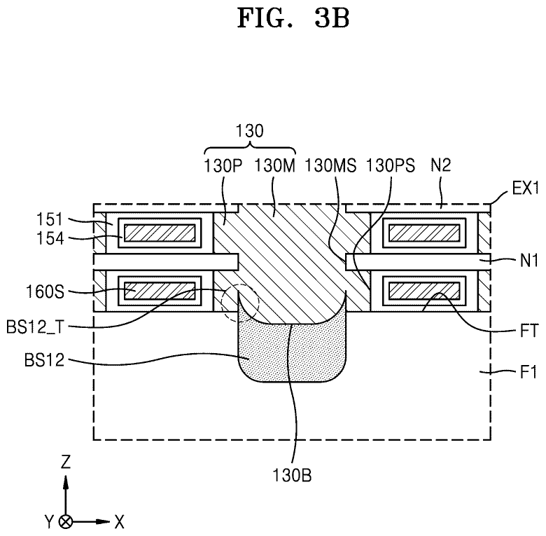

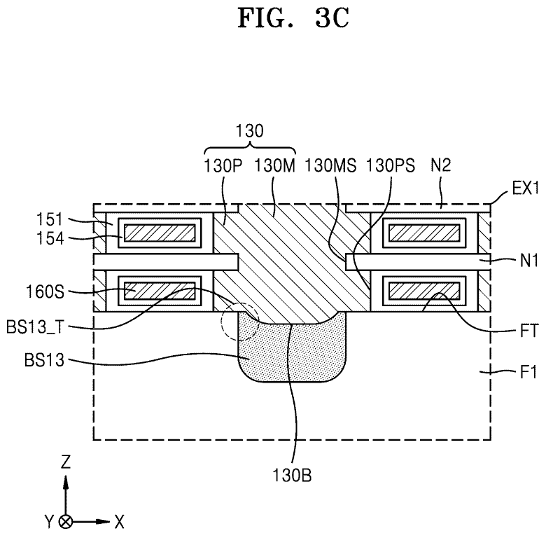

FIGS. 3A, 3B, and 3C are enlarged views of a region EX1 in FIG. 2.

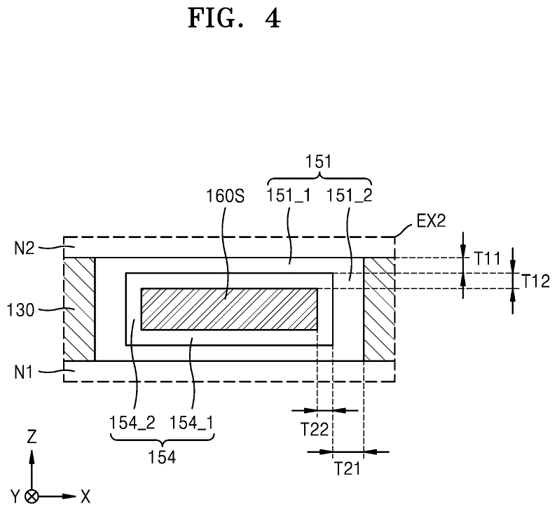

FIG. 4 is an enlarged view of a region EX2 in FIG. 2.

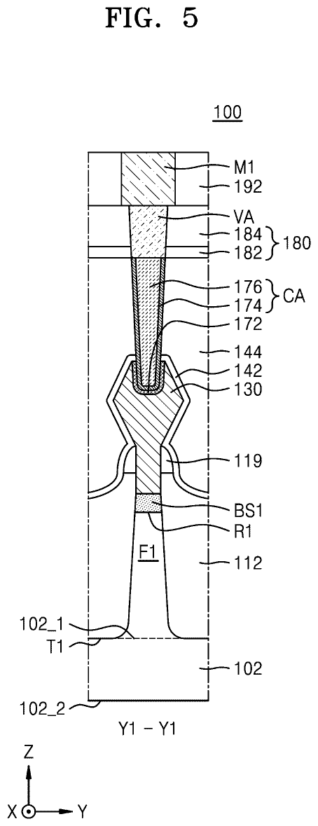

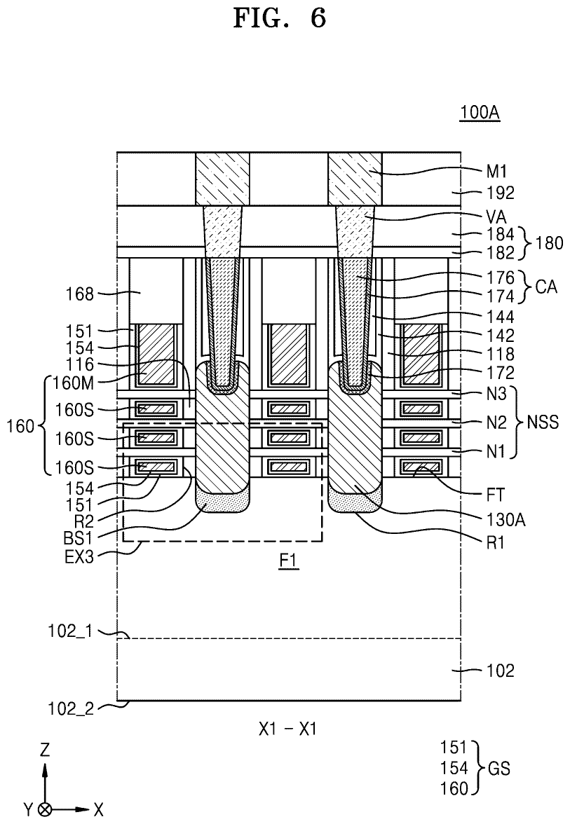

FIG. 5 is a cross-sectional view of the integrated circuit device 100 taken along line Y1-Y1 in FIG. 1.

The integrated circuit device 100 including a field-effect transistor having a gate-all-around structure including an active region of a nanowire or a nanosheet shape and a gate surrounding the active region is described with reference to FIGS. 2, 3A, 3B, 3C, 4, and 5. The term “surrounds” (or “surrounds,” or like terms), as may be used herein, is intended to broadly refer to an element, structure, or layer that extends around, envelops, circles, or encloses another element, structure or layer on all sides, although breaks or gaps may also be present. Thus, for example, a material layer having voids or gaps therein may still “surround” another layer that it encircles. For example, an integrated circuit device may include a multi-bridge channel field effect transistor (FET) (MBCFET) device. However, the inventive concept is not limited thereto, and the integrated circuit device 100 may also include a planar FET, a finFET, etc.

The integrated circuit device 100 may include an active region F1 protruding from a substrate 102 to limit a trench region Tl (refer to FIG. 5) on the substrate 102. A plurality of active regions F1 may extend lengthwise in parallel with each other on the substrate 102 in the first horizontal direction (X direction), and may be arranged apart from each other in the second horizontal direction (Y direction).

The substrate 102 may include a semiconductor, such as Si and Ge, or a compound semiconductor, such as SiGe, SiC, GaAs, InAs, InGaAs, and/or InP. The terms “SiGe”, “SiC”, “GaAs”, “InAs”, “InGaAs”, and/or “InP” used in embodiments of the inventive concept may be referred to as materials including elements included in each term, but may not be referred to as chemical formulas representing a stoichiometric relationship. The substrate 102 may include a conductive region, for example, a well doped with impurities, or a structure doped with impurities.

A device separation layer 112 may be arranged in the trench region TI limiting the active region F1. The device separation layer 112 may be on and at least partially cover portions of sidewalls of the active region F1 in the trench region TI, and may be spaced apart from the substrate 102 in the vertical direction (Z direction). The device separation layer 112 may include silicon oxide. The term “covers” (or “covering,” or like terms), as may be used herein, is intended to broadly refer to an element, structure or layer that is on or over another element, structure or layer, either directly or with one or more other intervening elements, structures or layers therebetween.

A plurality of gate lines 160 may be arranged on the active region F1. Each of the plurality of gate lines 160 may extend lengthwise in the second horizontal direction (Y direction). A plurality of nanosheet stacks NSS may be arranged on a fin upper surface FT of the active region F1 in regions where the active region F1 crosses the plurality of gate lines 160. Each of the plurality of nanosheet stacks NSS may include at least one nanosheet facing the fin upper surface FT at a location apart from the fin upper surface FT of the active region F1 in the vertical direction (Z direction). The term “nanosheet” used in the inventive concept may mean a conductive structure having a cross-section substantially perpendicular to a direction in which a current flows. The nanosheet should be understood as including nanowires.

Each of the plurality of nanosheet stacks NSS may include a first nanosheet N1, a second nanosheet N2, and a third nanosheet N3, which overlap each other on the active region F1 in the vertical direction (Z direction). Vertical distances (vertical direction distance) of the first nanosheet N1, the second nanosheet N2, and the third nanosheet N3 from the fin upper surface FT of the active region F1 may be different from each other. Each of the plurality of gate lines 160 may at least partially surround the first nanosheet N1, the second nanosheet N2, and the third nanosheet N3, which are included in the nanoshect stack NSS overlapping each other in the vertical direction (Z direction).

In FIG. 1, the case in which a planar shape of the nanosheet stack NSS has a roughly rectangular shape is illustrated, but the embodiments are not limited thereto. The nanosheet stack NSS may have various planar shapes according to a planar shape of each of the active region F1 and each of the plurality of gate lines 160. In the embodiment, the plurality of nanosheet stacks NSS and the plurality of gate lines 160 may be arranged on one active region F1, and a configuration is illustrated in which the plurality of nanosheet stacks NSS are arranged on one active region F1 in a line in the first horizontal direction (X direction). However, the number of nanosheet stacks NSS and the number of lines 160, which are arranged on one active region F1, may not be particularly limited.

Each of the first nanosheet N1, the second nanosheet N2, and the third nanosheet N3, which are included in the nanosheet stack NSS, may have a channel region. In some embodiments, each of the first nanosheet N1, the second nanosheet N2, and the third nanosheet N3 may have a thickness in a range of about 4 nm to about 6 nm, but the thickness thereof is not limited thereto. In this case, the thickness of each of the first nanosheet N1, the second nanosheet N2, and the third nanosheet N3 may mean a size in the vertical direction (Z direction). In some embodiments, the first nanosheet N1, the second nanosheet N2, and the third nanosheet N3 may have substantially the same thickness in the vertical direction (Z direction). In other embodiments, at least some of the first nanosheet N1, the second nanosheet N2, and the third nanosheet N3 may have substantially different thicknesses in the vertical direction (Z direction). In some embodiments, each of the first nanosheet N1, the second nanosheet N2, and the third nanosheet N3, which are included in the nanosheet stack NSS, may include a Si layer, a SiGe layer, or a combination thereof.

The first nanosheet N1, the second nanosheet N2, and the third nanosheet N3, which are included in one nanosheet stack NSS, may have the same size or similar sizes in the first horizontal direction (X direction). In other embodiments, unlike as illustrated in FIG. 2, at least some of the first nanosheet N1, the second nanosheet N2, and the third nanosheet N3 included in one nanosheet stack NSS may have different sizes from each other in the first horizontal direction (X direction). In this example, the case where each of the plurality of nanosheet stacks NSS includes three nanosheets is illustrated, but the FinFET embodiment is not limited thereto. For example, the nanosheet stack NSS may include at least one nanosheet, and the number of nanosheets constituting the nanosheet stack NSS is not particularly limited.

Each of the plurality of gate lines 160 may include a main gate portion 160M and a plurality of sub-gate portions 160S. The main gate portion 160M may be on and at least partially cover an upper surface of the nanosheet stack NSS, and extend lengthwise in the second horizontal direction (Y direction). The plurality of sub-gate portions 160S may be connected to the main gate portion 160M in one body, and each of the plurality of sub-gate portions 160S may be arranged between each of the first nanosheet N1, the second nanosheet N2, and the third nanosheet N3, and between the first nanosheet N1 and the active region F1. In the vertical direction (Z direction), the thickness of each of the plurality of sub-gate portions 160S may be less than the thickness of the main gate portion 160M.

Each of the plurality of gate lines 160 may include a metal, metal nitride, metal carbide, or a combination thereof. The metal may include one of Ti, W, Ru, Nb, Mo, Hf, Ni, Co, Pt, Yb, Tb, Dy, Er, and Pd. The metal nitride may include one of TiN and TaN. The metal carbide may include TiAlC. However, the materials constituting the plurality of gate lines 160 are not limited to the examples described above.

An interface dielectric layer 151 and a high dielectric layer 154 may be arranged between the nanosheet stack NSS and the gate line 160. The interface dielectric layer 151 and the high dielectric layer 154 may surround the gate line 160. Any one gate line 160 among the plurality of gate lines 160, and the interface dielectric layer 151 and the high dielectric layer 154, which at least partially surround the any one gate line 160, may constitute a “gate structure GS”. A relative thickness of each of the interface dielectric layer 151 and the high dielectric layer 154 is not limited to those illustrated in FIGS. 2, 3A, 3B, and 3C. Depending on necessity, the integrated circuit device 100 may include a portion where the thickness of the interface dielectric layer 151 is greater than the thickness of the high dielectric layer 154, a portion where the thickness of the interface dielectric layer 151 is less than the thickness of the high dielectric layer 154, and a portion where the thickness of the interface dielectric layer 151 is the same as or similar to the thickness of the high dielectric layer 154.

In a cross-section view in the second horizontal direction (Y direction), the interface dielectric layer 151 and the high dielectric layer 154 may at least partially surround each of the first through third nanosheets N1 through N3 to at least partially surround a periphery of each of the first through third nanosheets N1 through N3 between each of the first through third nanosheets N1 through N3 and the gate line 160.

In some embodiments, the interface dielectric layer 151 may include a low dielectric material layer having a dielectric constant of about 9 or less, for example, a silicon oxide layer, a silicon oxynitride layer, or a combination thereof. For example, the interface dielectric layer 151 may include a silicon oxide layer. In some embodiments, the high dielectric layer 154 may include a material having a higher dielectric constant than the silicon oxide layer. For example, the high dielectric layer 154 may have a dielectric constant of about 10 to about 25. The high dielectric layer 154 may include hafnium oxide, but embodiments are not limited thereto.

The interface dielectric layer 151 may be connected to (in contact with) a surface of each of a plurality of active regions F1, and a surface of each of the first through third nanosheets N1 through N3 respectively included in each of the plurality of nanosheet stacks NSS, and may surround each of the plurality of gate lines 160. The high dielectric layer 154 may be arranged between the interface dielectric layer 151 and the gate line 160, and may be connected to (in contact with) a bottom surface and sidewalls of the gate line 160.

A plurality of active region recesses R1 may be formed on the active region F1. A vertical level of the lowermost surface of each of the plurality of active region recesses R1 may be lower than a vertical level of the fin upper surface FT of the active region F1.

The plurality of source/drain regions 130 may be arranged between each of the plurality of gate lines 160. Each of the plurality of source/drain regions 130 may be arranged at a position adjacent to at least one gate line 160 among the plurality of gate lines 160. Each of the plurality of source/drain areas 130 may have surfaces facing the first nanosheet N1, the second nanosheet N2, and the third nanosheet N3, which are included in the adjacent nanosheet stack NSS.

As illustrated in FIGS. 3A, 3B, and 3C, each of the plurality of source/drain regions 130 may include a center portion 130M and a protrusion portion 130P extending from the center portion 130M toward the gate structure GS, that is, a gate structure including a plurality of sub-gate structure 160S, and the interface dielectric layer 151 and the high dielectric layer 154, which at least partially surround the plurality of sub-gate portions 160S. The center portion 130M may be connected to (in contact with) a surface of each of the first through third nanosheets N1 through N3 included in each of the plurality of nanosheet stacks NSS. The center portion 130M may include a first sidewall 130MS arranged on the same surface as sidewalls of each of the first through third nanosheets N1 through N3 included in each of the plurality of nanosheet stacks NSS. A sidewall of each of the first through third nanosheets N1 through N3 included in each of the plurality of nanosheet stacks NSS may constitute the first sidewall 130MS of the center portion 130M.

The protrusion portion 130P may be connected to (in contact with) a surface of the interface dielectric layer 151 included in a plurality of gate structures GS. The protrusion portion 130P may include a second sidewall 130PS arranged on the same surface as the sidewalls of the interface dielectric layer 151 included in each of the plurality of gate structures GS. The sidewall of the interface dielectric layer 151 included in each of the plurality of gate structures GS may constitute the second sidewall 130PS of the protrusion portion 130P. The first sidewall 130MS of the center portion 130M and the second sidewall 130PS of the protrusion portion 130P may be arranged on different flat surfaces. The protrusion portion 130P may be plural, and a plurality of protrusion portions 130P may overlap the plurality of gate structures GS in the first horizontal direction (X direction).

Each of the plurality of source/drain regions 130 may include an epitaxially grown semiconductor layer. In some embodiments, each of the plurality of source/drain regions 130 may include an epitaxially grown Si layer, an epitaxially grown SiC layer, or a plurality of epitaxially grown SiGe layers. When the source/drain region 130 includes an NMOS transistor, the source/drain region 130 may include an Si layer doped with an n-type dopant or an SiC layer doped with an n-type dopant. The n-type dopant may include phosphorus (P), arsenic (As), or antimony (Sb). When the source/drain region 130 includes an NMOS transistor, the source/drain region 130 may include an SiGe layer doped with a p-type dopant. The p-type dopant may include boron (B) or gallium (Ga).

The plurality of nanosheet stacks NSS may be arranged on the fin upper surface FT of each of the plurality of active regions F1 in regions where the plurality of active regions F1 intersect respectively the plurality of gate lines 160, and a plurality of FETs may be formed in regions where the plurality of active regions F1 intersect the plurality of gate lines 160 on the substrate 102.

In some embodiments, the source/drain region 130 of a first group constituting the PMOS transistor among the plurality of source/drain regions 130 may be electrically connected to a plurality of power source lines to receive a voltage of positive electrical potential, and the source/drain region 130 of a second group constituting the NMOS transistor among the plurality of source/drain regions 130 may be electrically connected to a plurality of ground lines to receive a ground voltage or a voltage of negative electrical potential.

As illustrated in FIG. 2, both sidewalls of each of the plurality of sub-gate structure 160S included in the gate line 160 may be spaced apart from the source/drain region 130 with the interface dielectric layer 151 and the high dielectric layer 154 therebetween. Each of the interface dielectric layer 151 and the high dielectric layer 154 may include a portion between the sub-gate portion 160S included in the gate line 160 and each of the first through third nanosheets N1 through N3, and a portion between the sub-gate portion 160S included in the gate line 160 and the source/drain region 130.

As illustrated in FIG. 4, the interface dielectric layer 151 may include a first portion 151_1 extending to each of the first through third nanosheets N1 through N3, and a second portion 151_2 extending onto the source/drain region (130, in detail, the protrusion portion 130P of the source/drain region 130). The high dielectric layer 154 may include a first portion 154_1 extending to each of the first through third nanosheets N1 through N3, and a second portion 154_2 extending onto the source/drain region (130, in detail, the protrusion portion 130P of the source/drain region 130). The first portion 151_1 of the interface dielectric layer 151 may have a first thickness T11 in the vertical direction (Z direction), and the second portion 151_2 of the interface dielectric layer 151 may have a second thickness T21 in the first horizontal direction (X direction). The first portion 154_1 of the high dielectric layer 154 may have a first thickness T12 in the vertical direction (Z direction), and the second portion 154_2 of the high dielectric layer 154 may have a second thickness T22 in the first horizontal direction (X direction). The first thickness T11 of the first portion 151_1 of the interface dielectric layer 151 may be different from the second thickness T21 of the second portion 151_2. For example, the first thickness T11 of the first portion 151_1 of the interface dielectric layer 151 may be less than the second thickness T21 of the second portion 151_2, and the second thickness T21 of the second portion 151_2 may be greater than the first thickness T11 of the first thickness T11. The first thickness T12 of the first portion 154_1 of the high dielectric layer 154 may be substantially the same as the second thickness T22 of the second portion 154_2. Because the second thickness T21 of the second portion 151_2 of the interface dielectric layer 151 is greater than the first thickness T11 of the first portion 151_1, a leakage current between the source/drain region 130 and the gate line 160 may be effectively reduced.

As illustrated in FIG. 2, in the embodiment, under the source/drain region 130, a lower insulating spacer BS1 may be arranged in the active region recess R1 extending from the fin upper surface FT of the active region F1. The lower insulating spacer BS1 may be arranged between the source/drain region 130 and the active region F1 in the vertical direction (Z direction). In addition, the lower insulating spacer BS1 may be connected to (in contact with) a surface of the active region F1 in the first horizontal direction (X direction), and may be connected to (in contact with) a surface of the device separation layer 112 in the second horizontal direction (Y direction). The lower insulating spacer BS1 may overlap the active region F1 in the first horizontal direction (X direction), and may overlap the device separation layer 112 in the second horizontal direction (Y direction).

As illustrated in FIGS. 3A, 3B, and 3C, lower insulating spacers BS11, BS12, and BS13 may surround a bottom surface 130B of the source/drain region (130, in detail, the center portion 130M of the source/drain region 130). The bottom surface 130B of the source/drain region 130 may be spaced apart from the active region F1 due to the lower insulating spacers BS11, BS12, and BS13. Because the lower insulating spacers BS11, BS12, and BS13 are formed to at least partially fill the inside of the active region recess R1, the lower insulating spacers BS11, BS12, and BS13 may have upper surfaces of a concave shape with respect to the source/drain region 130, and may have upper surfaces of shapes in which the vertical levels thereof increase toward periphery regions from center regions of the lower insulating spacers BS11, BS12, and BS13 in the first horizontal direction (X direction). Uppermost end portions BS11_T, BS12_T, and BS13_T of the lower insulating spacers BS11, BS12, and BS13 may include portions on outermost peripheries among the lower insulating spacers BS11, BS12, and BS13, respectively.

As illustrated in FIG. 3A, the lower insulating spacer BS11 may overlap only the active region F1 in the first horizontal direction (X direction). The uppermost end portion BS11_T of the lower insulating spacer BS11 may have a same vertical level as a vertical level of the fin upper surface FT of the active region F1.

As illustrated in FIG. 3B, the lower insulating spacer BS12 may overlap portions of the active region F1 and the gate structure GS in the first horizontal direction (X direction). For example, the lower insulating spacer BS12 may overlap the active region F1 in the first horizontal direction (X direction), and may overlap a portion surrounding the sub-gate portion 160S at the lowermost end of the plurality of sub-gate portions 160S and the sub-gate portion 160S at the lowermost end of the interface dielectric layer 151, and a portion surrounding the sub-gate portion 160S at the lowermost end of the high dielectric layer 154. The uppermost end portion BS12_T of the lower insulating spacer BS12 may have a higher vertical level than a vertical level of the fin upper surface FT of the active region F1. For example, the uppermost end portion BS12_T of the lower insulating spacer BS12 may overlap a portion surrounding the sub-gate portion 160S at the lowermost end of the plurality of sub-gate portions 160S and the sub-gate portion 160S at the lowermost end of the interface dielectric layer 151, and a portion surrounding the sub-gate portion 160S at the lowermost end of the high dielectric layer 154.

As illustrated in FIG. 3C, the lower insulating spacer BS13 may overlap only the active region F1 in the first horizontal direction (X direction). Although not illustrated, the lower insulating spacer BS13 may also overlap a portion at least partially surrounding the sub-gate portion 160S at the lowermost end of the plurality of sub-gate portions 160S and the sub-gate portion 160S at the lowermost end of the interface dielectric layer 151, and a portion at least partially surrounding the sub-gate portion 160S at the lowermost end of the high dielectric layer 154.

The uppermost end portion BS13_T of the lower insulating spacer BS13 may have a same vertical level as a vertical level of the fin upper surface FT of the active region F1. Although not illustrated, the uppermost end portion BS13_T of the lower insulating spacer BS13 may overlap a portion at least partially surrounding the sub-gate portion 160S at the lowermost end of the plurality of sub-gate portions 160S and the sub-gate portion 160S at the lowermost end of the interface dielectric layer 151, and a portion at least partially surrounding the sub-gate portion 160S at the lowermost end of the high dielectric layer 154.

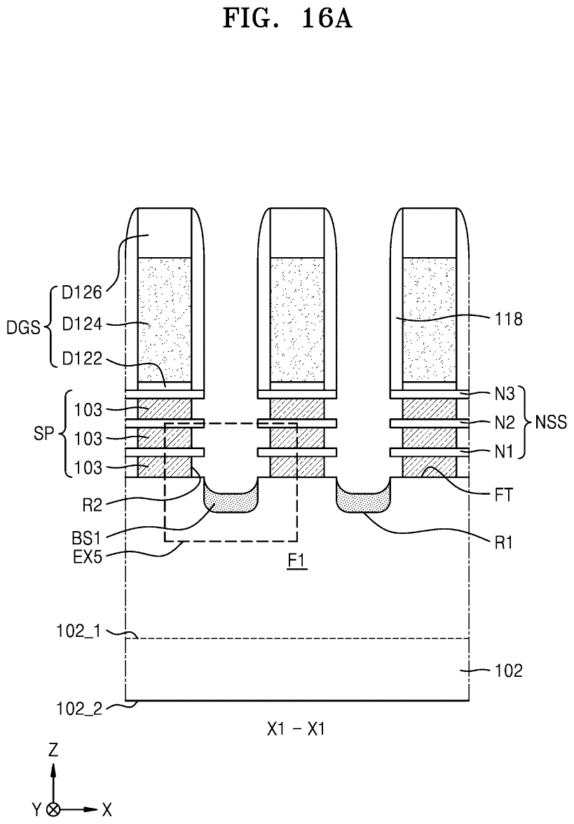

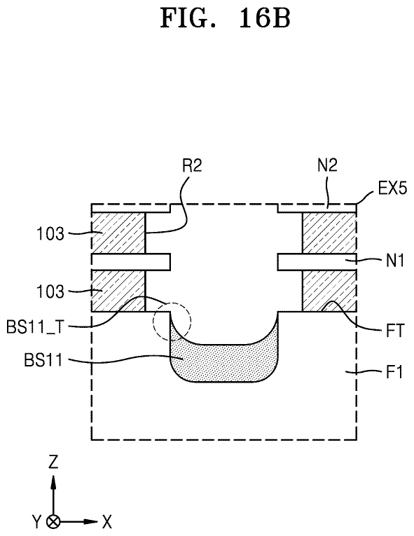

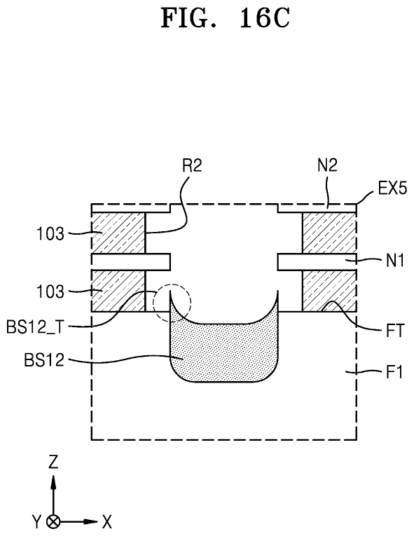

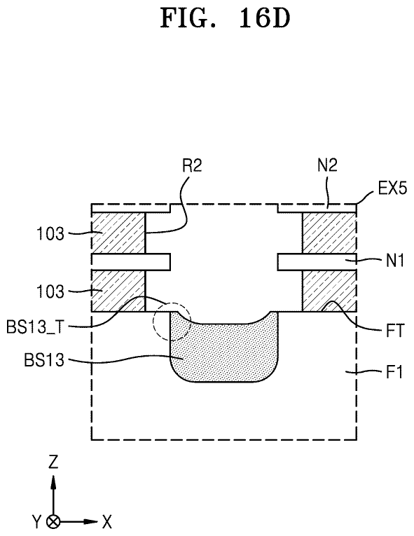

The lower insulating spacer BS13 may have an upper surface of a concave shape with respect to the source/drain region 130, and may have an upper surface of a shape in which the vertical level increases from the center region toward the periphery region of the lower insulating spacer BS13, but may include a portion where the vertical level is maintained relatively uniform in the periphery region. In a process of selectively etching a portion of the sacrificial semiconductor layer (refer to 103 in FIGS. 16A through 16D) after the lower insulating spacer BS13 is formed in a manufacturing process, because the thickness of the periphery region of the lower insulating spacer BS13 is relatively less than that of the center region of the lower insulating spacer BS13, a portion of the lower insulating spacer BS13 in the periphery region may be removed together with a portion of the lower insulating spacer BS13 in the center region to be formed in a shape similar to that in FIG. 3C.

In some embodiments, the lower insulating spacer BS1 may include an insulating material, and may have a single layer or a multilayer. For example, the lower insulating spacer BS1 may include silicon nitride, silicon oxide, or a combination thereof.

A capping insulating pattern 168 may be arranged on the interface dielectric layer 151 and the gate line 160. The capping insulating pattern 168 may be on and at least partially cover an upper surface of the main gate portion 160M, and an upper surface of a portion of the interface dielectric layer 151 at least partially surrounding the main gate portion 160M. The capping insulating pattern 168 may include a silicon nitride layer and a silicon oxide layer.

Both sidewalls of each of the gate line 160 and the capping insulating pattern 168 may be at least partially covered by a first insulating spacer 118. The first insulating spacer 118 may cover both sidewalls of the main gate portion 160M on an upper surface of the plurality of nanosheet stacks NSS. The first insulating spacer 118 may be spaced apart from the gate line 160 with the interface dielectric layer 151 and the high dielectric layer 154 therebetween.

A plurality of second insulating spacers 119 on and at least partially covering one sidewall of the source/drain region 130 and the other sidewall facing the one sidewall may be arranged on the upper surface of the device separation layer 112. In some embodiments, each of the plurality of second insulating spacers 119 may be connected to the first insulating spacer 118 adjacent thereto in one body. In other embodiments, at least some of the plurality of second insulating spacers 119 may be omitted.

Each of a plurality of first insulating spacers 118 and the plurality of second insulating spacers 119 may include silicon nitride, silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC” used in the inventive concept may be referred to as materials including elements included in each term, but may not be referred to as chemical formulas representing a stoichiometric relationship.

The interface dielectric layer 151 and the high dielectric layer 154 may be on and at least partially cover the surface of the active region F1, and the surface of each of the first through third nanosheets N1 through N3 included in the nanosheet stack NSS in a space limited by a pair of the first insulating spacers 118. The interface dielectric layer 151 and the high dielectric layer 154 may be on and at least partially cover a bottom surface and both sidewalls of the gate line 160. The high dielectric layer 154 may be connected to (in contact with) the bottom surface and both sidewalls of the gate line 160, and the interface dielectric layer 151 may be spaced apart from the gate line 160 with the high dielectric layer 154 therebetween.

A metal silicide layer 172 may be arranged on an upper surface of each of the plurality of source/drain regions 130. The metal silicide layer 172 may include a metal including Ti, W, Ru, Nb, Mo, Hf, Ni, Co, Pt, Yb, Tb, Dy, Er, and/or Pd. For example, the metal silicide layer 172 may include titanium silicide, but is not limited thereto.

An insulating liner 142 and an inter-gate insulating layer 144 may be sequentially arranged on the plurality of source/drain areas 130 and a plurality of metal silicide layers 172. The first insulating spacer 118 and the plurality of source/drain areas 130 may be covered with the insulating liner 142. In some embodiments, the insulating liner 142 may include silicon nitride (SIN), SiCN, SiBN, SiON, SiOCN, SiBCN, or a combination thereof, but is not limited thereto. The inter-gate insulating layer 144 may include a silicon oxide layer, but embodiments are not limited thereto.

A plurality of source/drain contacts CA may be respectively arranged on the plurality of source/drain areas 130. Each of the plurality of source/drain contacts CA may penetrate the insulating liner 142 and the inter-gate insulating layer 144 in the vertical direction (Z direction), and may be configured to be electrically connected to at least one source/drain region 130 among the plurality of source/drain regions 130. Each of the plurality of source/drain contacts CA may be connected to (in contact with) the metal silicide layer 172 formed on the source/drain region 130. Each of the plurality of source/drain contacts CA may be configured to be electrically connected to the source/drain region 130 via the metal silicide layer 172. Each of the plurality of source/drain contacts CA may be spaced apart from the main gate portion 160M of the gate line 160 with the first insulating spacer 118 therebetween in the first horizontal direction (X direction).

Each of the plurality of source/drain contacts CA may include a conductive barrier layer 174 and a contact plug 176. A bottom surface and sidewalls of the contact plug 176 may be on and at least partially covered by the conductive barrier layer 174. The conductive barrier layer 174 may include a metal or conductive metal nitride. For example, the conductive barrier layer 174 may include Ti, Ta, W, TiN, TaN, WN, WCN, TiSiN, TaSiN, WSiN, or a combination thereof, but embodiments are not limited thereto. The contact plug 176 may include molybdenum (Mo), tungsten (W), cobalt (Co), ruthenium (Ru), manganese (Mn), titanium (Ti), tantalum (Ta), aluminum (Al), copper (Cu), or a combination thereof, or an alloy thereof, but embodiments are not limited thereto. In other embodiments, the conductive barrier layer 174 may be omitted from each of the plurality of source/drain contacts CA.

An upper surface of each of the source/drain contact CA, the capping insulating pattern 168, the insulating liner 142, and the inter-gate insulating layer 144 may be at least partially covered by an upper insulating structure 180. The upper insulating structure 180 may include an etching stop layer 182 and an interlayer insulating layer 184, which are sequentially stacked on each of the plurality of source/drain contacts CA, a plurality of capping insulating patterns 168, and the inter-gate insulating layer 144. The etching stop layer 182 may include SiC, SiN, nitrogen-doped silicon carbide (SiC:N), SiOC, AlN, AlON, AIO, AlOC, or a combination thereof. The interlayer insulating layer 184 may include an oxide layer, a nitride layer, an ultra-low k (ULK) layer having an ultra-low dielectric constant K of about 2.2 to about 2.4, or a combination thereof. For example, the interlayer insulating layer 184 may include a tetra-ethyl-ortho-silicate (TEOS) layer, a high density plasma (HDP) layer, a boro-phospho-silicate glass (BPSG) layer, a flowable chemical vapor deposition (FCVD) oxide layer, an SiON layer, an SiOC layer, an SiCOH layer, or a combination thereof, but embodiments are not limited thereto.

A plurality of source/drain via contacts VA may be respectively arranged on the plurality of source/drain contacts CA. Each of the plurality of source/drain via contacts VA may penetrate or extend through the upper insulating structure 180 and be electrically connected to (in contact with) the source/drain contact CA. Each of the plurality of source/drain areas 130 may be configured to be electrically connected to the source/drain via contact VA via the metal silicide layer 172 and the source/drain contact CA. A lower surface of each of the plurality of source/drain via contacts VA may be electrically connected to (in contact with) an upper surface of the source/drain contact CA. Each of the plurality of source/drain via contacts VA may include Mo or W, but embodiments are not limited thereto.

An upper surface of the upper insulating structure 180 and each of the plurality of source/drain via contacts VA may be at least partially covered by an upper insulating layer 192. The constituent material of the upper insulating layer 192 may be substantially the same as the constituent material of the interlayer insulating layer 184 described above.

A plurality of upper wiring layers MI may be arranged to penetrate or extend through the upper insulating layer 192. Each of the plurality of upper wiring layers MI may be electrically connected to one source/drain via contact VA thereunder, selected from the plurality of source/drain via contacts VA. The plurality of upper wiring layers MI may include Mo, Cu, W, Co, Ru, Mn, Ti, Ta, Al, a combination thereof, or an alloy thereof, but embodiments are not limited thereto.

FIG. 6 is a diagram of a region corresponding to a cross section of the integrated circuit device 100A taken along line X1-X1 in FIG. 1, and is a cross-sectional view illustrating the integrated circuit device 100A according to another embodiment.

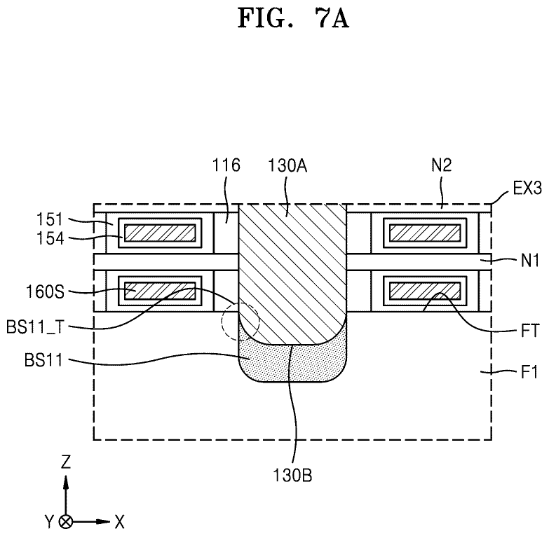

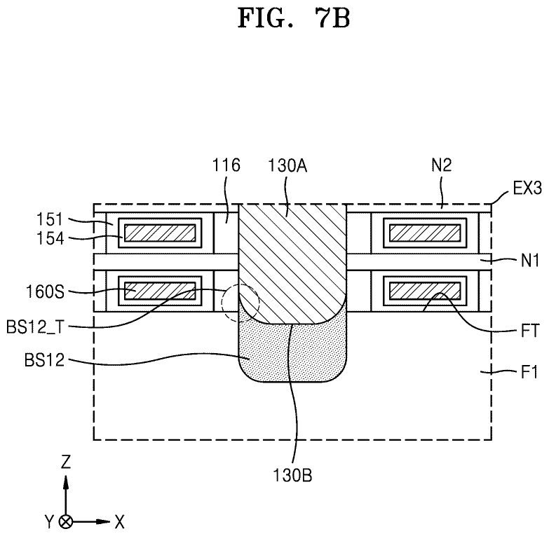

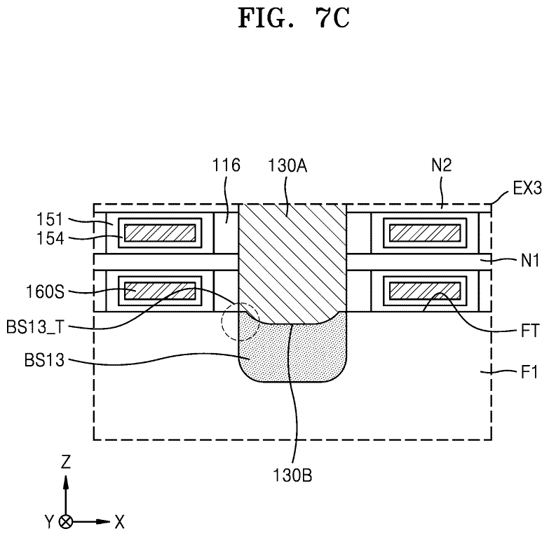

FIGS. 7A, 7B, and 7C are enlarged views of a region EX3 in FIG. 6.

Because the integrated circuit device 100A described with reference to FIGS. 6, 7A, 7B, and 7C is configured similarly to the integrated circuit device 100 described above, hereinafter, descriptions of components similar to those of the integrated circuit device 100 may be simplified or omitted, and only components different from those of the integrated circuit device 100 are described in detail.

Referring to FIGS. 6, 7A, 7B, and 7C, the integrated circuit device 100A may include a source/drain region 130A, and an inner side insulating spacer 116 arranged between the source/drain region 130A and the gate structure (GS, in detail, the interface dielectric layer 151).

The inner side insulating spacer 116 may be arranged in plural on sidewalls of the source/drain region 130A. Each of a plurality of inner side insulating spacers 116 may be arranged between the fin upper surface FT of the active region F1 and the first nanosheet N1, between the first nanosheet N1 and the second nanosheet N2, and between the second nanosheet N2 and the third nanosheet N3. The plurality of inner side insulating spacers 116 may include silicon nitride.

The source/drain region 130A may extend along sidewalls of the nanosheet stack NSS and sidewalls of the inner side insulating spacer 116. The sidewalls of the nanosheet stack NSS and the sidewalls of the inner side insulating spacer 116 may constitute a portion of the sidewalls of the source/drain region 130A. The sidewalls of the nanosheet stack NSS and the sidewalls of the inner side insulating spacer 116 may be arranged on the same flat surfaces.

As illustrated in FIG. 7A, the lower insulating spacer BS11 may overlap only the active region F1 in the first horizontal direction (X direction). The uppermost end portion BS11_T of the lower insulating spacer BS11 may have a same vertical level as a vertical level of the fin upper surface FT of the active region F1. The uppermost end portion BS11_T of the lower insulating spacer BS11 may be connected to (in contact with) the inner side insulating spacer 116.

As illustrated in FIG. 7B, the lower insulating spacer BS12 may overlap portions of the active region F1, the gate structure GS, and the inner side insulating spacer 116 in the first horizontal direction (X direction). For example, the lower insulating spacer BS12 may overlap the active region F1 in the first horizontal direction (X direction), may overlap a portion surrounding the sub-gate portion 160S at the lowermost end of the plurality of sub-gate portions 160S and the sub-gate portion 160S at the lowermost end of the interface dielectric layer 151, and a portion surrounding the sub-gate portion 160S at the lowermost end of the high dielectric layer 154, and may overlap the inner side insulating spacer 116 on the sub-gate portion 160S at the lowermost end of the plurality of inner side insulating spacers 116. The uppermost end portion BS12_T of the lower insulating spacer BS12 may have a higher vertical level than a vertical level of the fin upper surface FT of the active region F1. For example, the uppermost end portion BS12_T of the lower insulating spacer BS12 may overlap, in the first horizontal direction (X direction), a portion surrounding the sub-gate portion 160S at the lowermost end of the plurality of sub-gate portions 160S and the sub-gate portion 160S at the lowermost end of the interface dielectric layer 151, and a portion surrounding the sub-gate portion 160S at the lowermost end of the high dielectric layer 154, and may overlap the inner side insulating spacer 116 on the sub-gate portion 160S at the lowermost end of the plurality of inner side insulating spacers 116. The uppermost end portion BS12_T of the lower insulating spacer BS12 may be connected to (in contact with) the inner side insulating spacer 116.

As illustrated in FIG. 7C, the lower insulating spacer BS13 may overlap only the active region F1 in the first horizontal direction (X direction). The uppermost end portion BS13_T of the lower insulating spacer BS13 may have a same vertical level as a vertical level of the fin upper surface FT of the active region F1. The lower insulating spacer BS13 may have an upper surface of a concave shape with respect to the source/drain region 130, and may have an upper surface of a shape in which the vertical level increases from the center region toward the periphery region of the lower insulating spacer BS13, but may include a portion where the vertical level is maintained relatively uniform in the periphery region. The uppermost end portion BS13_T of the lower insulating spacer BS13 may be connected to (in contact with) the inner side insulating spacer 116.

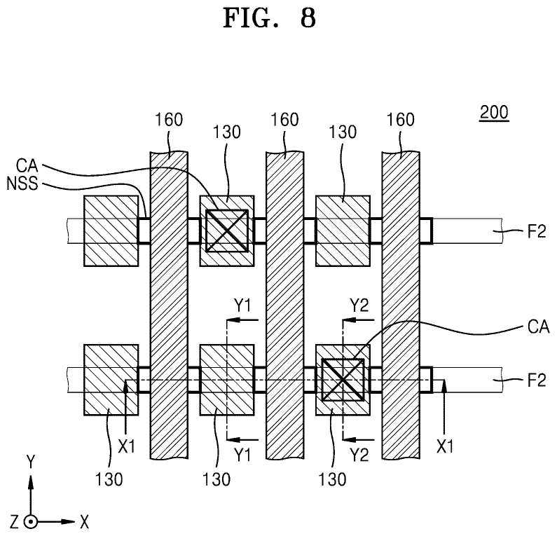

FIG. 8 is a layout of an integrated circuit device 200 according to an embodiment.

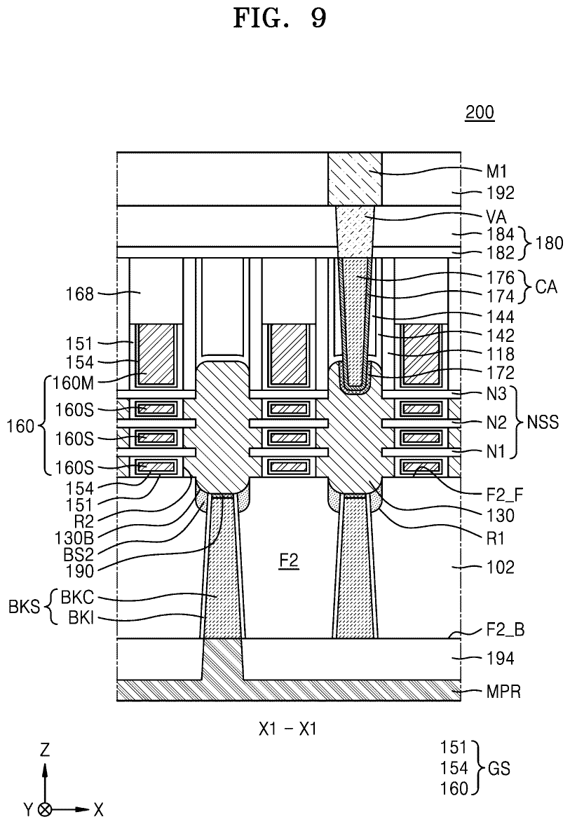

FIG. 9 is a cross-sectional view of the integrated circuit device 200 taken along line X1-X1 in FIG. 8.

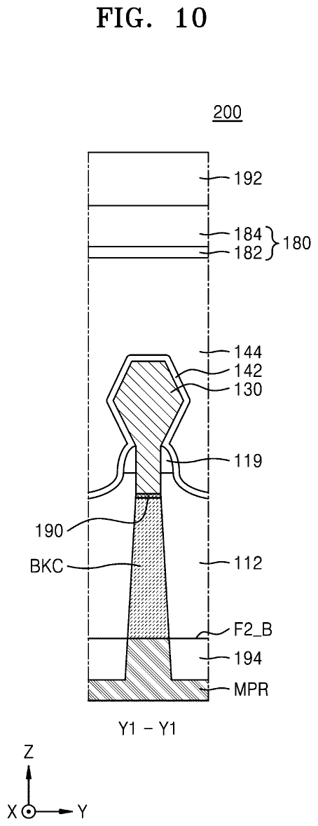

FIG. 10 is a cross-sectional view of the integrated circuit device 200 taken along line Y1-Y1 in FIG. 8.

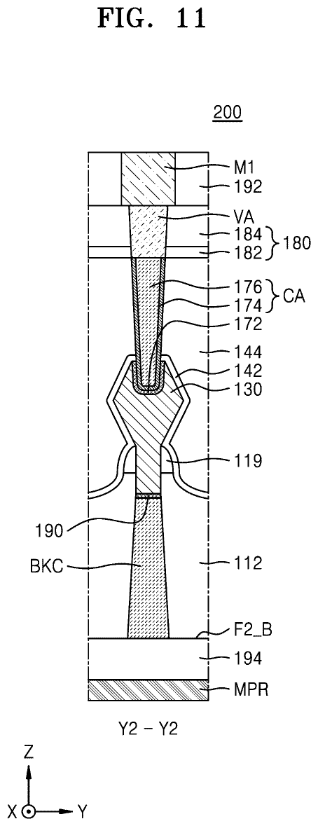

FIG. 11 is a cross-sectional view of the integrated circuit device 200 taken along line Y2-Y2 in FIG. 8.

Because the integrated circuit device 200 described with reference to FIGS. 8, 9, 10, and 11 is configured similarly to the integrated circuit device 100 described above, hereinafter, descriptions of components similar to those of the integrated circuit device 100 may be simplified or omitted, and only components different from those of the integrated circuit device 100 are described in detail.

Referring to FIGS. 8, 9, 10, and 11, the integrated circuit device 200 may include a backside contact structure BKS penetrating or extending through an active region F2 and connected to the source/drain region 130, and a lower insulating spacer BS2 arranged on sidewalls of the backside contact structure BKS.

A plurality of active regions F2 may extend lengthwise in the first horizontal direction (X direction), extend in parallel with each other, and be arranged apart from each other in the second horizontal direction (Y direction). Each of the plurality of active regions F2 may include a frontside surface F2_F and a backside surface F2_B facing the frontside surface F2_F. The plurality of active regions F2 may include a semiconductor, such as Si and/or Ge, or a compound semiconductor, such as SiGe, SiC, GaAs, InAs, InGaAs, and/or InP.

In some embodiments, the backside contact structure BKS may extend from the backside surface F2_B of the plurality of active regions F2, and penetrate the active region F2 and the lower insulating spacer BS2 to be arranged under the source/drain region 130. The backside contact structure BKS may include a backside contact BKC and a backside insulating spacer BK1. The backside insulating spacer BK1 may be arranged between the backside contact BKC and the active region F2 closest to the backside contact BKC, and between the backside contact BKC and the lower insulating spacer BS2. The backside contact BKC may be spaced apart from the active region F2 with the backside insulating spacer BK1 therebetween in the first horizontal direction (X direction).

A metal silicide layer 190 may be arranged between the source/drain region 130 and the backside contact structure BKS. The metal silicide layer 190 may be electrically connected to (in contact with) the source/drain region 130 and the backside contact structure BKS. The backside contact structure BKS may penetrate or extend through in the vertical direction (Z direction) a space between two active regions F2 adjacent to each other in the first horizontal direction (X direction) among the plurality of active regions F2 to be connected to (in contact with) the metal silicide layer 190.

The backside contact BKC may be configured to be electrically connected to the source/drain region 130 via the metal silicide layer 190. The constituent material of the metal silicide layer 190 may be the same as that of the metal silicide layer 172 described above. In some embodiments, the backside contact BKC may include only a metal plug including a single metal. In other embodiments, the backside contact BKC may include the metal plug and a conductive barrier layer at least partially surrounding the metal plug. The metal plug may include Mo, W, Co, Ru, Mn, Ti, Ta, Al, Cu, or a combination thereof, or an alloy thereof, but embodiments are not limited thereto. The conductive barrier layer may include a metal or conductive metal nitride. For example, the conductive barrier layer may include Ti, Ta, W, TiN, TaN, WN, WCN, TiSiN, TaSiN, WSiN, or a combination thereof, but embodiments are not limited thereto.

The lower insulating spacer BS2 may be on and at least partially cover a portion of sidewalls of the backside contact structure BKS in the first horizontal direction (X direction), and the active region F2 may be on and at least partially cover the remaining portion of the sidewalls of the backside contact structure BKS in the first horizontal direction (X direction). For example, the lower insulating spacer BS2 may be on and at least partially cover an upper portion of sidewalls of the backside contact structure BKS in the first horizontal direction (X direction), and the active region F2 may be on and at least partially cover a lower portion of the sidewalls of the backside contact structure BKS in the first horizontal direction (X direction). The lower insulating spacer BS2 and the backside contact structure BKS may at least partially surround the bottom surface 130B of the source/drain region 130. Although not illustrated, the lower insulating spacer BS2 may be configured to be similar to the lower insulating spacer BS1 described above, and may have various shapes as described in the descriptions with reference to FIGS. 3A through 3C.

In some embodiments, the integrated circuit device 200 may include a lower insulating layer 194 on and at least partially covering the backside surface F2_B of each of the plurality of active regions F2, and a plurality of lower wiring structures MPR penetrating or extending through the lower insulating layer 194 in the vertical direction (Z direction). The plurality of lower wiring structures MPR may include the lower wiring structure MPR connected to the backside contact BKC. In some embodiments, the constituent material of the lower insulating layer 194 may be generally the same as the constituent material of the upper insulating layer 192 described above. The constituent material of each of the plurality of lower wiring structures MPR may be generally the same as the constituent material of the plurality of upper wiring layers MI described above.

However, the inventive concept is not limited to the integrated circuit devices 100, 100A, and 200 described above, and an integrated circuit device having various structures by applying various transformations and changes within the scope of the technical idea of the inventive concept may be provided. For example, in the integrated circuit device 200, similar to the integrated circuit device 100A, an integrated circuit device including the source/drain region 130A instead of the source/drain region 130 and including the inner side insulating spacer 116 may also be configured.

According to embodiments, the lower insulating spacers BS1 and BS2 under the source/drain region 130 may be included, and the lower insulating spacers BS1 and BS2 may reduce the amount of leakage current under the source/drain region 130 to provide integrated circuit devices 100, 100A, and 200 having improved reliability.

In addition, according to embodiments, because a process of increasing the doping concentration (dose) of a well in the active region F1 for reducing the leakage current under the source/drain region 130 may be omitted, by reducing the occurrence of threading dislocation density (TDD) defects, the integrated circuit devices 100, 100A, and 200 having improved reliability may be provided.

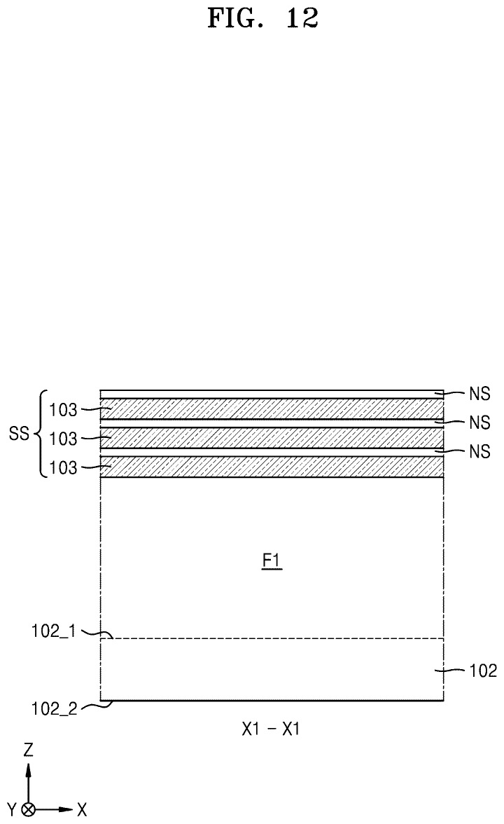

FIGS. 12 through 24 are cross-sectional views illustrating a method of manufacturing the integrated circuit device 100, according to embodiments. Referring to FIGS. 12 through 24, an example method of manufacturing the integrated circuit device 100 described with reference to FIGS. 1, 2, 3A, 3B, 3C, 4 and 5 is described, and the same reference numerals as those in FIGS. 1, 2, 3A, 3B, 3C, 4 and 5 may denote the same members, and detailed descriptions thereof are omitted herein.

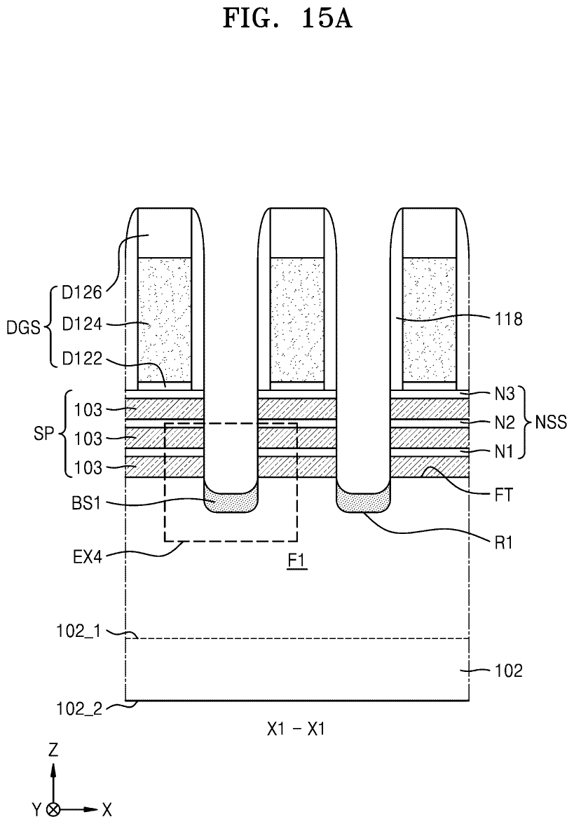

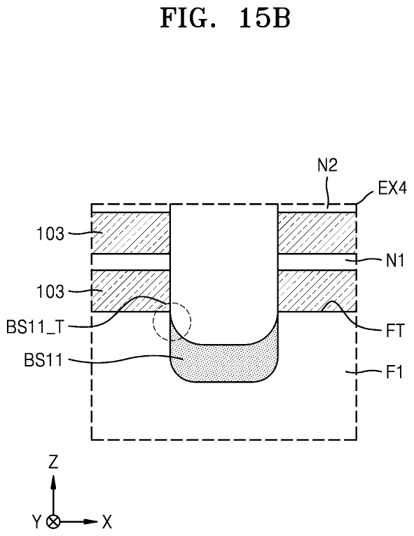

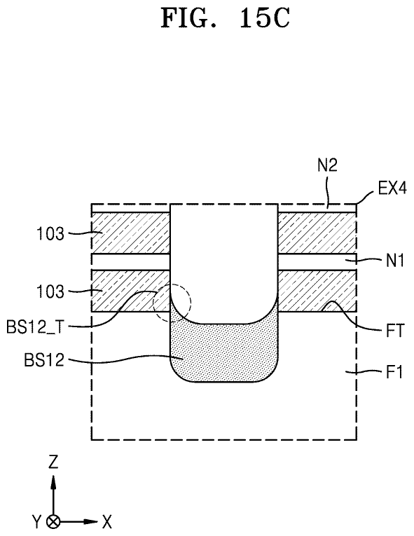

FIGS. 12 through 14, 15A, 16A, and 17 through 24 are diagrams illustrating a region corresponding to a cross section of the integrated circuit device 100 taken along line X1-X1 in FIG. 1, and FIGS. 15B and 15C are enlarged views of a region EX4 in FIG. 15A, and FIGS. 16B to 16D are enlarged views of a region EX5 in FIG. 16A.

Referring to FIG. 12, a stacked structure SS in which the plurality of sacrificial semiconductor layers 103 and the plurality of nanosheet semiconductor layers NS are alternately stacked on the substrate 102 may be formed. The plurality of sacrificial semiconductor layers 103 and the plurality of nanosheet semiconductor layers NS may include semiconductor materials having different etching selectivities from each other. In some embodiments, the plurality of nanosheet semiconductor layers NS may include an Si layer, and the plurality of sacrificial semiconductor layers 103 may include an SiGe layer. In some embodiments, the Ge content ratio in the plurality of sacrificial semiconductor layers 103 may be constant. The SiGe layer constituting the plurality of sacrificial semiconductor layers 103 may have a constant Ge content ratio selected in the range of about 5 atom % to about 60 atom %, for example, about 10 atom % to about 40 atom %. The Ge content ratio in the SiGe layer constituting the plurality of sacrificial semiconductor layers 103 may be variously selected as desired.

The substrate 102 may include a semiconductor element, such as Si and/or Ge, or a compound semiconductor, such as SiGe, SiC, GaAs, InAs, InGaAs, and/or InP.

Each of the plurality of sacrificial semiconductor layers 103 and the plurality of nanosheet semiconductor layers NS, which constitute the stacked structure SS, may be formed by using an epitaxial growth process. In some embodiments, the plurality of nanosheet semiconductor layers NS may include a single crystal Si layer, and the plurality of sacrificial semiconductor layers 103 may include an SiGe layer.

Thereafter, the sacrificial semiconductor layer 103, the plurality of nanosheet semiconductor layers NS, and a portion of the substrate 102 may be etched to form the plurality of active regions F1 on the substrate 102 extending in the first horizontal direction (X direction). In this manner, a first surface 102_1 of the substrate 102 may be formed, and the plurality of active regions F1 may be arranged on the first surface 102_1. The stacked structure SS of the plurality of sacrificial semiconductor layers 103 and the plurality of nanosheet semiconductor layers NS may remain on the fin upper surface FT of each of the plurality of active regions F1.

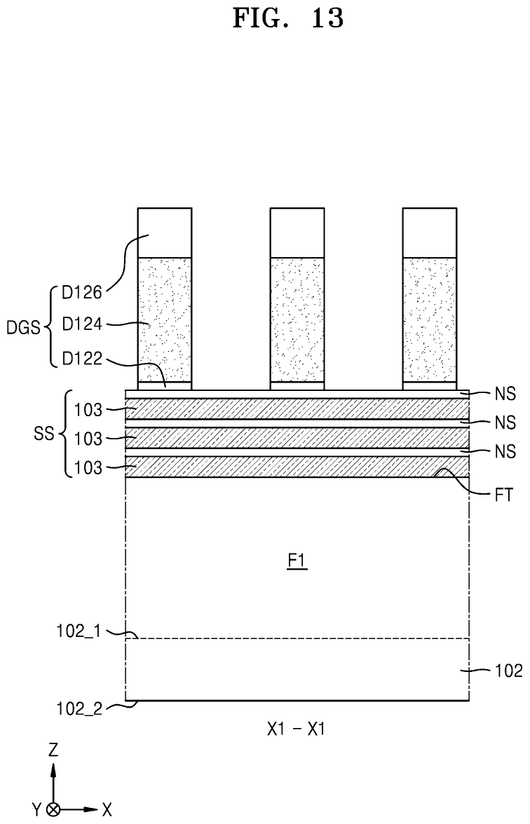

Referring to FIG. 13, a plurality of dummy gate structures DGS may be formed on the stacked structure of the plurality of sacrificial semiconductor layers 103 and the plurality of nanosheet semiconductor layers NS.

Each of the plurality of dummy gate structures DGS may be formed to extend lengthwise in the second horizontal direction (Y direction). Each of the plurality of dummy gate structures DGS may have a structure in which an oxide layer D122, a dummy gate layer D124, and a capping layer D126 are sequentially stacked. In some embodiments, the dummy gate layer D124 may include polysilicon, and the capping layer D126 may include a silicon nitride layer.

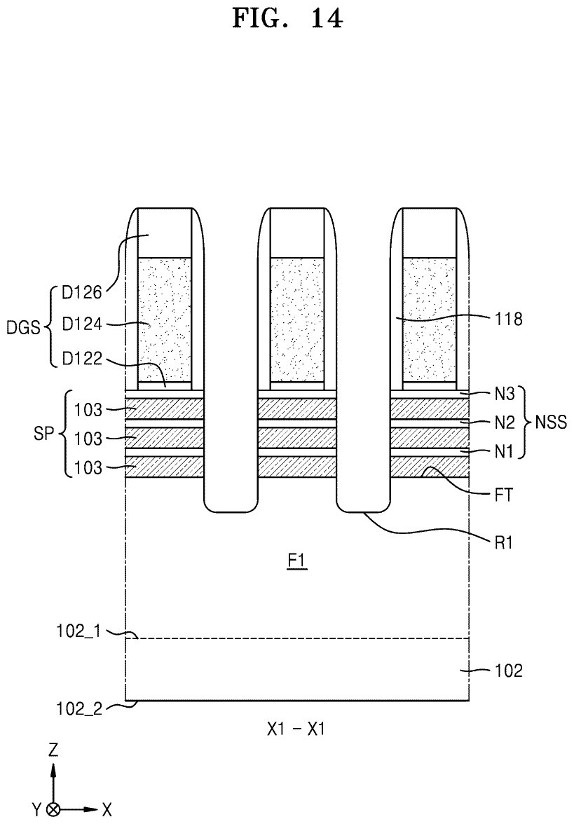

Referring to FIG. 14, after forming the plurality of first insulating spacers 118 covering both sidewalls of each of the plurality of dummy gate structures DGS, a portion of the plurality of sacrificial semiconductor layers 103 and a portion of the plurality of nanosheet semiconductor layers NS may be etched by using the plurality of dummy gate structures DGS and the plurality of first insulating spacers 118 as etching masks. In this manner, the plurality of nanosheet semiconductor layers NS may be divided into the plurality of nanosheet stacks NSS each of which includes the first nanosheet N1, the second nanosheet N2, and the third nanosheet N3.

By using the etching process, a stacked pattern SP including the plurality of sacrificial semiconductor layers 103 and the plurality of nanosheets N1, N2, and N3 may be formed.

The plurality of active region recesses R1 at lest partially exposing sidewalls of the stacked pattern SP may be formed by using the etching process. To form the plurality of active region recesses R1, a dry etching operation, a wet etching operation, or a combination thereof may be performed. The term “exposed” (or “exposes,” or like terms) may be used herein to describe relationships between elements and/or with reference to intermediate manufacturing processes, but may not require exposure of the entirety of a particular element in the completed device.

Referring to FIGS. 15A, 15B, and 15C, the lower insulating spacer BS1 may be formed in the active region recess R1. Because the lower insulating spacer BS1 is formed to at least partially fill the inside of the active region recess R1, the lower insulating spacer BS1 may have an upper surface of a concave shape with respect to the source/drain region 130, and may have an upper surface of a shape in which the vertical level thereof increases toward the periphery region from the center region of the lower insulating spacer BS1 in the first horizontal direction (X direction). The uppermost end portions BS11_T, BS12_T, and BS13_T of the lower insulating spacers BS11, BS12, and BS13, respectively, may include portions on the outermost periphery of the lower insulating spacer BS1.

As illustrated in FIG. 15B, the lower insulating spacer BS11 may overlap only the active region F1 in the first horizontal direction (X direction). The uppermost end portion BS11_T of the lower insulating spacer BS11 may have the same vertical level as the vertical level of the fin upper surface FT of the active region F1.

As illustrated in FIG. 15C, the lower insulating spacer BS12 may overlap portions of the active region F1 and the sacrificial semiconductor layer 103 in the first horizontal direction (X direction). For example, the lower insulating spacer BS12 may overlap the active region F1 in the first horizontal direction (X direction), and may overlap a portion of the sacrificial semiconductor layer 103 at the lowermost end of the plurality of sacrificial semiconductor layers 103. The uppermost end portion BS12_T of the lower insulating spacer BS12 may have a higher vertical level than the vertical level of the fin upper surface FT of the active region F1. For example, the uppermost end portion BS12_T of the lower insulating spacer BS12 may overlap a portion of the sacrificial semiconductor layer 103 at the lowermost end of the plurality of sacrificial semiconductor layers 103 in the first horizontal direction (X direction).

Referring to FIGS. 16A through 16D, by removing a portion of each of the plurality of sacrificial semiconductor layers 103 among the stacked patterns SP exposed by each of the plurality of active region recesses R1, a plurality of side recesses R2 may be formed. To form the plurality of side recesses R2, an etching composition material may be applied to the stacked pattern SP by using the plurality of active region recesses R1.

In some embodiments, as illustrated in FIGS. 16B and 16C, by applying the etching composition material to the stacked pattern SP, a portion of each of the plurality of sacrificial semiconductor layers 103 among the plurality of nanosheets N1, N2, and N3 and the plurality of sacrificial semiconductor layers 103 may be selectively removed. In some embodiments, as illustrated in FIG. 16D, in a process of removing selectively a portion of each of the plurality of sacrificial semiconductor layers 103 among the plurality of nanosheets N1, N2, and N3 and the plurality of nanosheets N1, N2, and N3 by applying the etching composition material to the stacked pattern SP, depending on the chemical composition, although portions of the lower insulating spacers (BS1, BS11, and BS12 in FIGS. 15A, 15B, and 15C, respectively) are removed together, the lower insulating spacer BS13 may also be formed as illustrated in FIG. 16D. Because the thickness of the periphery region of the lower insulating spacer BS1 is relatively less than that of the center region thereof, a portion of the lower insulating spacer BS1 to be removed may correspond to a position on the periphery region of the lower insulating spacer BS1.

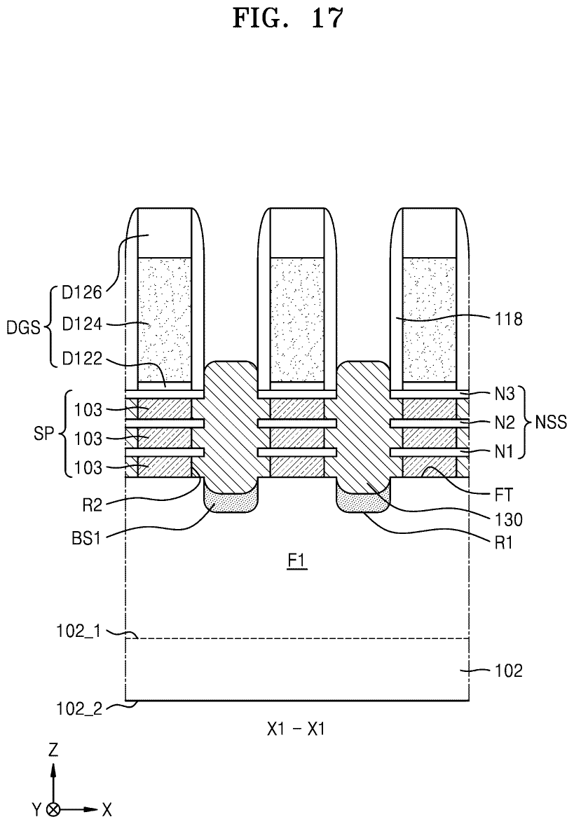

Referring to FIG. 17, the plurality of first drain regions 130 may be formed respectively on a plurality of lower insulating spacers BS1. In some embodiments, to form the plurality of source/drain regions 130, a semiconductor material may be epitaxially grown from the sidewall of each of the first nanosheet N1, the second nanosheet N2, and the third nanosheet N3 included in the nanosheet stack NSS, and from a sidewall of each of the plurality of sacrificial semiconductor layers 103. Because the surface of active region F1 under a bottom surface of each of the plurality of active region recesses R1 is at least partially surrounded by the lower insulating spacer BS1, the semiconductor material may not be epitaxially grown on the surface of the active region F1 under the bottom surface of the plurality of active region recesses R1.

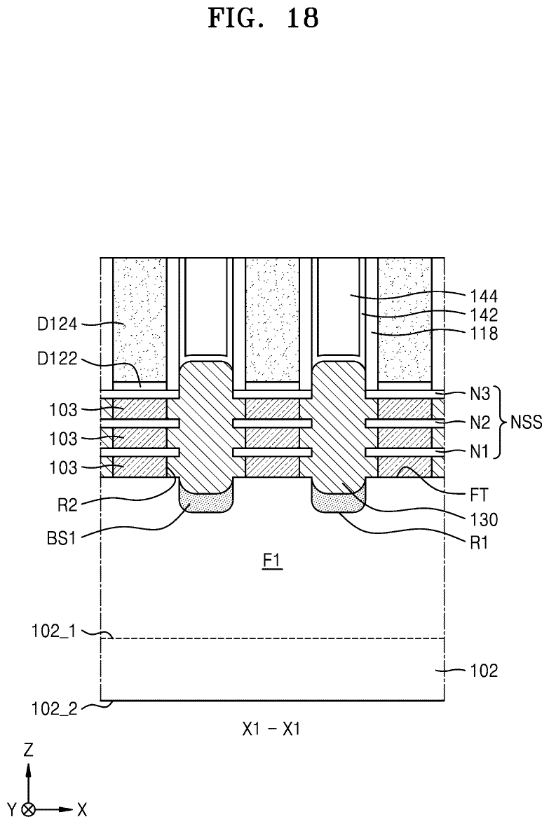

Referring to FIG. 18, after the insulating liner 142 on and at least partially covering the resultant product of FIG. 17, in which the plurality of source/drain areas 130 are formed, is formed, and the inter-gate insulating layer 144 is formed on the insulating liner 142, the insulating liner 142 and the inter-gate insulating layer 144 may be planarized to at least partially expose the upper surface of the capping layer D126.

Thereafter, the capping layer D126 may be removed to expose the upper surface of the dummy gate layer D124, and the insulating liner 142 and the inter-gate insulating layer 144 may be partially removed such that the upper surface of the inter-gate insulating layer 144 and the upper surface of the dummy gate layer D124 are approximately on the same level.

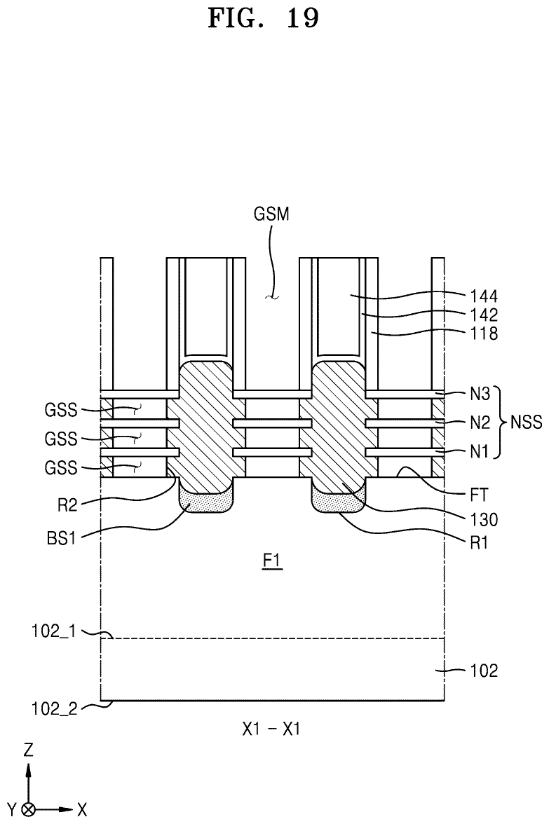

Referring to FIG. 19, the dummy gate layer D124 and the oxide layer D122 under the dummy gate layer D124 may be removed to prepare the main gate space GSM, and the plurality of nanosheet stacks NSS may be at least partially exposed through the main gate space GSM.

Next, the plurality of sacrificial semiconductor layers 103 remaining on the active region F1 may be removed through the main gate space GSM, and may provide the sub-gate space GSS between each of the first nanosheet N1, the second nanosheet N2, and the third nanosheet N3 and between the first nanosheet N1 and the fin upper surface FT.

In some embodiments, to selectively remove the plurality of sacrificial semiconductor layers 103, a difference in etching selectivity between the first nanosheet N1, the second nanosheet N2, and the third nanosheet N3, and the plurality of sacrificial semiconductor layers 103 may be used. An etchant in a liquid or gaseous state may be used to selectively remove the plurality of sacrificial semiconductor layers 103. In some embodiments, to selectively remove the plurality of sacrificial semiconductor layers 103, a CH₃COOH-based etchant, such as an etchant solution containing a mixture of CH₃COOH, HNO₃, and HF, and an etchant solution containing a mixture of CH₃COOH, H₂O₂, and HF, may be used, but embodiments are not limited thereto.

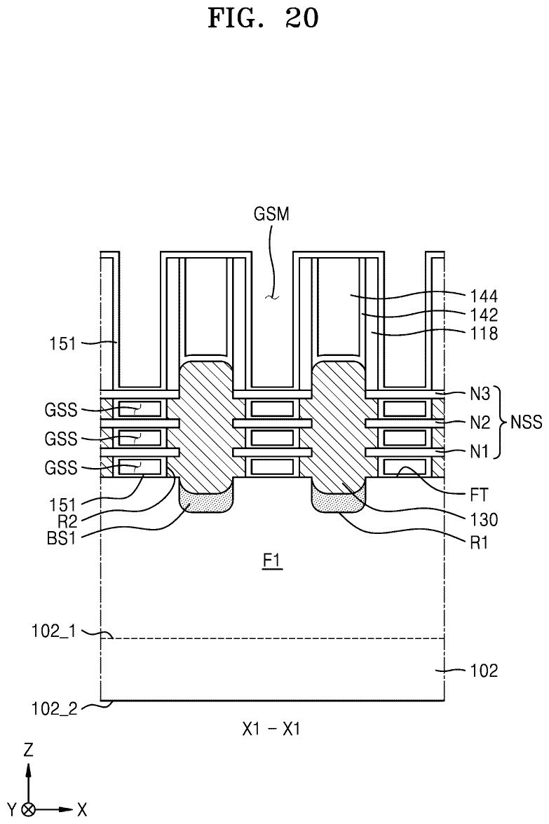

Referring to FIG. 20, the interface dielectric layer 151 may be formed in the main gate space GSM and the sub-gate space GSS. The interface dielectric layer 151 covering the exposed surface of the third nanosheet N3 may be formed in the main gate space GSM. The interface dielectric layer 151 covering the first through third nanosheets N1 through N3 may be formed in the sub-gate space GSS. An atomic layer deposition (ALD) process may be used for forming the interface dielectric layer 151.

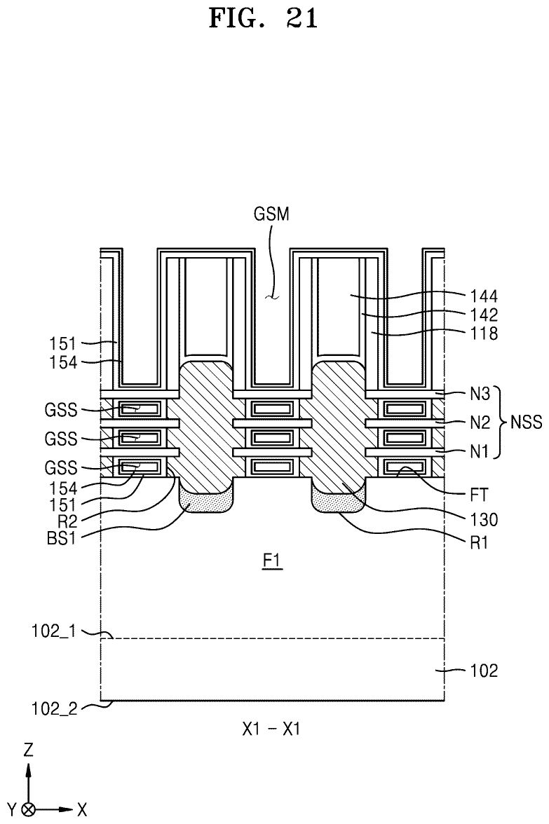

Referring to FIG. 21, on the resultant product of FIG. 20, the high dielectric layer 154 covering conformally the surface of the interface dielectric layer 151 may be formed. The ALD process may be used for forming the high dielectric layer 154.

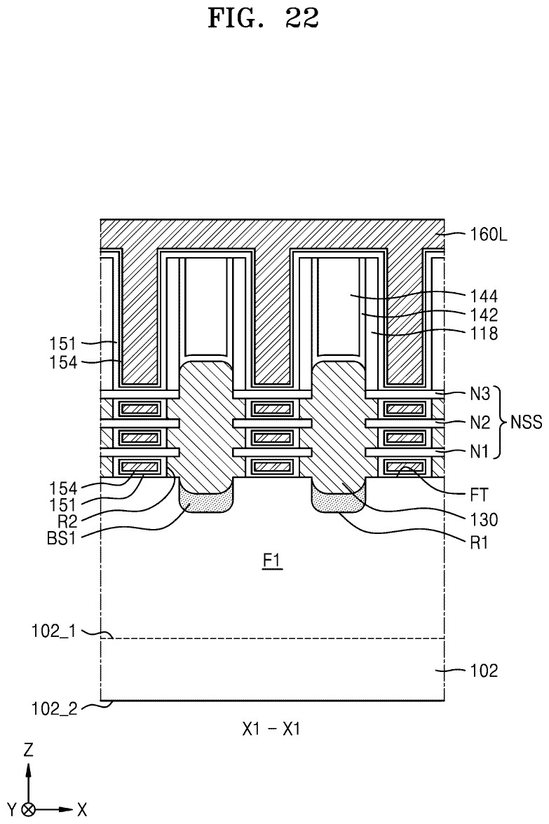

Referring to FIG. 22, a gate forming conductive layer 160L filling the main gate space GSM and the sub-gate space GSS (refer to FIG. 21) may be formed on the high dielectric layer 154. The gate forming conductive layer 160L may include a metal, a metal nitride, metal carbide, or a combination thereof. An ALD process or a chemical vapor deposition (CVD) process may be used for forming the gate forming conductive layer 160L.

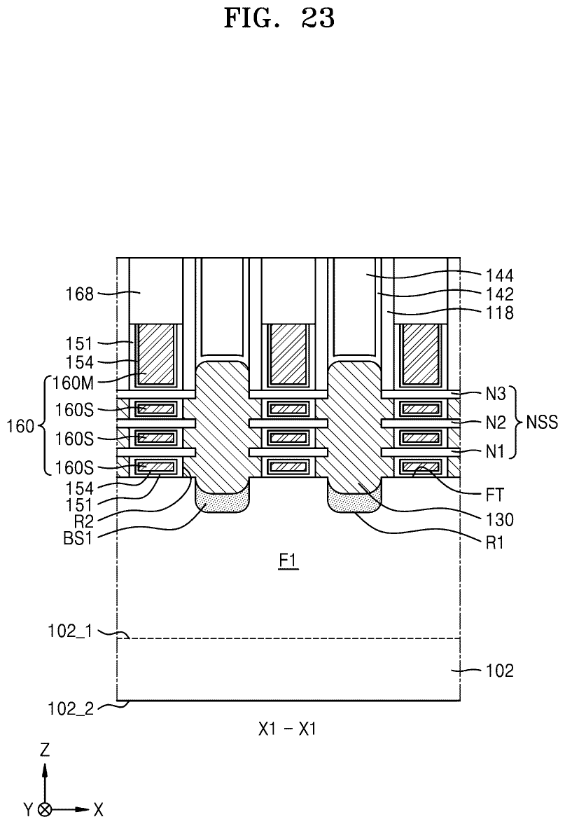

Referring to FIG. 23, thereafter, a height of each of the gate line 160, the interface dielectric layer 151, and the high dielectric layer 154 may be lowered by removing a portion of the upper surface of each of the gate line 160, the interface dielectric layer 151, and the high dielectric layer 154, and the plurality of capping insulating patterns 168 covering the upper surface of each of the gate line 160, the interface dielectric layer 151, and the high dielectric layer 154 may be formed.

A portion of the gate forming conductive layer 160L may be removed from the upper surface thereof so that the upper surface of the inter-gate insulating layer 144 is at least partially exposed and a portion of the upper side of the main gate space (refer to GSM in FIG. 9) is again emptied. As a result, the plurality of gate lines 160 may be formed from the gate forming conductive layer 160L.

In this case, in the main gate space GSM, the interface dielectric layer 151, the high dielectric layer 154, and the first insulating spacer 118 may also have a portion of each upper side thereof consumed and accordingly, may have each height thereof lowered. Thereafter, the capping insulating pattern 168 filling the main gate space GSM may be formed on the gate line 160.

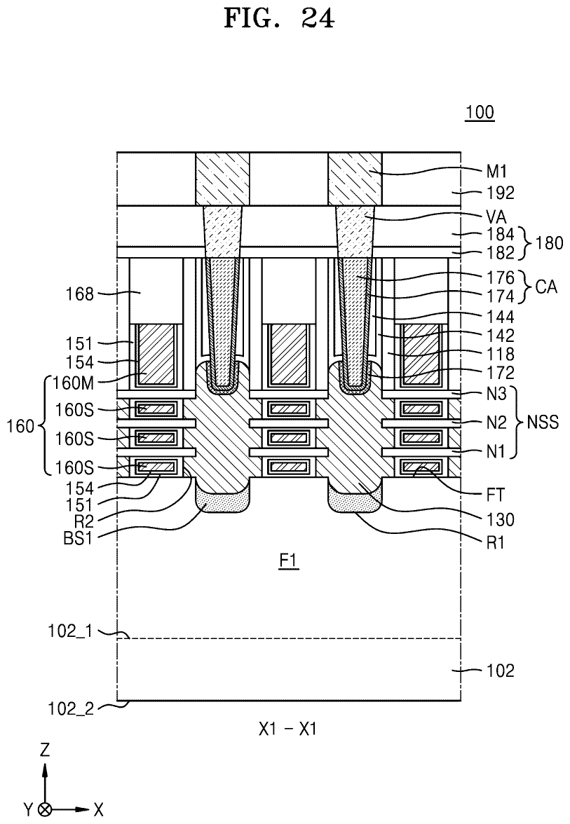

Referring to FIG. 24, a plurality of source/drain contact holes (not illustrated), which penetrate or extend through an insulating structure including the insulating liner 142 and the inter-gate insulating layer 144, and expose the source/drain region 130, may be formed. Through the source/drain contact hole (not illustrated), a certain region of the plurality of source/drain regions 130 may be removed by using an anisotropic etching process, and accordingly, the plurality of source/drain contact holes (not illustrated) may extend longer toward the substrate 102.

Thereafter, a portion of the source/drain region 130 exposed by the plurality of source/drain contact holes (not illustrated) may be consumed to form the metal silicide layer 172. In some embodiments, to form the metal silicide layer 172, a metal liner (not illustrated) on and at least partially covering conformally the at least partially exposed surface of the source/drain region 130 may be formed, and by applying heat treatment, a process inducing a reaction between the source/drain region 130 and a metal constituting the metal liner may be included. After the metal silicide layer 172 is formed, a remaining portion of the metal liner may be removed. In some embodiments, when the metal silicide layer 172 includes titanium silicide, the metal liner may include a Ti layer. The source/drain contact CA including the conductive barrier layer 174 and the contact plug 176 may be formed on the metal silicide layer 172.

Thereafter, the upper insulating structure 180 may be formed by forming sequentially the etching stop layer 182 and the interlayer insulating layer 184 covering the upper surface of each of the inter-gate insulating layer 144, the plurality of source/drain contacts CA, and the plurality of capping insulating patterns 168, and the plurality of via contacts VA penetrating or extending through the upper insulating structure 180 in the vertical direction (Z direction) and being respectively connected to the plurality of source/drain contacts CA may be formed.

Thereafter, the upper insulating layer 192 on and at least partially covering the upper surface of each of the upper insulating structure 180 and the plurality of source/drain via contacts VA may be formed, and the plurality of upper wiring layers MI penetrating or extending through the upper insulating layer 192 in the vertical direction (Z direction) and being respectively electrically connected to the plurality of source/drain via contacts VA may be formed.

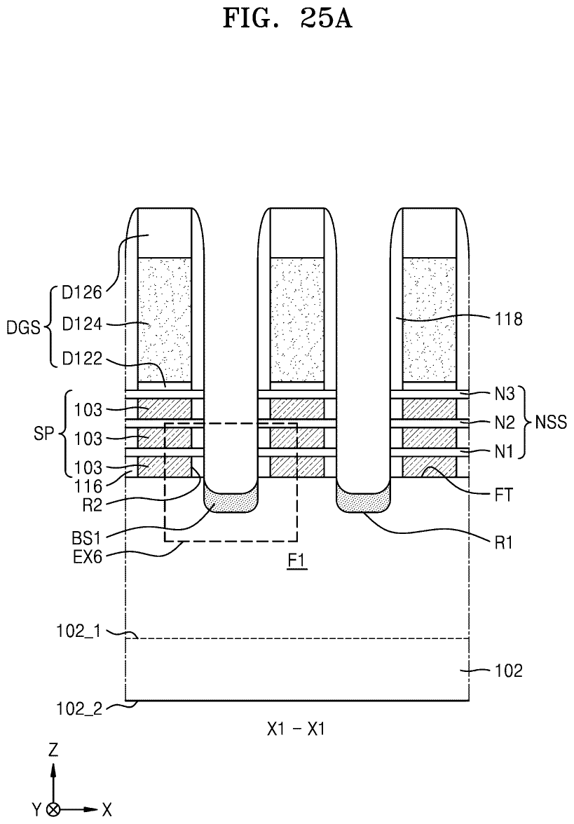

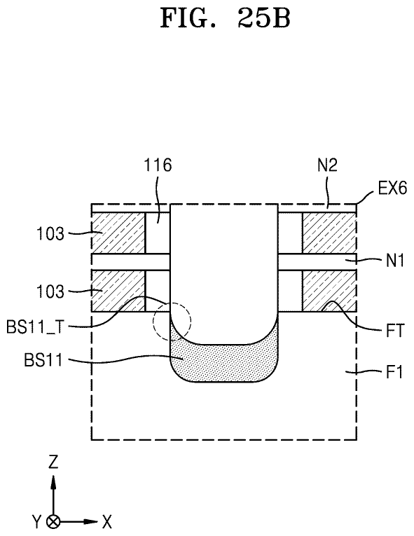

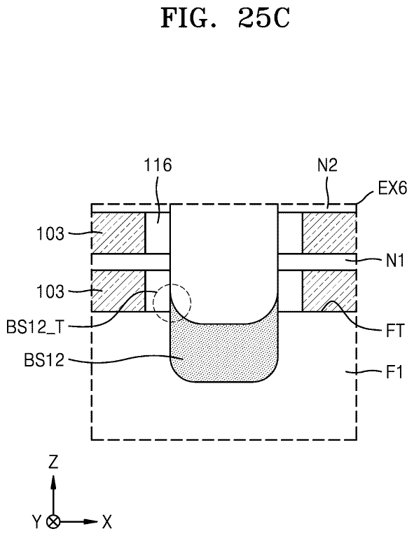

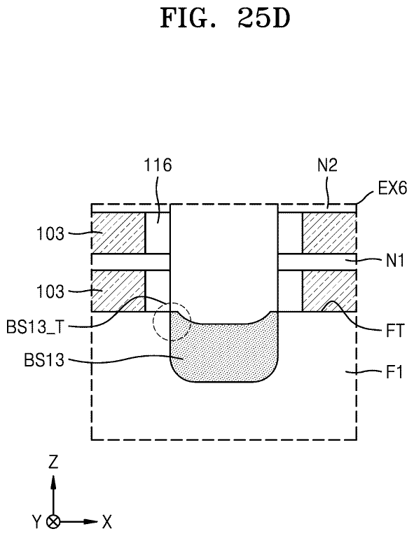

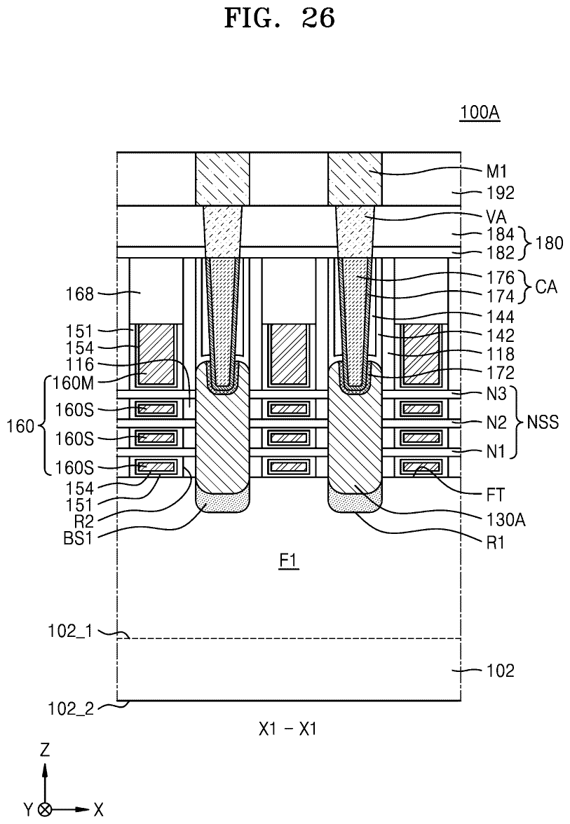

FIGS. 25A, 25B, 25C, and 25D are cross-sectional views illustrating a method of manufacturing the integrated circuit device 100A, according to embodiments. With reference to FIGS. 25A, 25B, 25C, 25D, and 26, an example method of manufacturing the integrated circuit device 100A described with reference to FIGS. 6 and 7A through 7C are described, the same reference numerals as those in FIGS. 6 and 7A through 7C represent the same members, and descriptions thereof are omitted herein.

FIGS. 25A and 26 are diagrams of regions corresponding to the cross-section taken along line X1-X1 in FIG. 1, and FIGS. 25B, 25C, and 25D are enlarged views of a region EX6 in FIG. 25A.

Referring to FIGS. 25A, 25B, 25C, and 25D, from the resultant products of FIGS. 16A, 16B, 16C, and 16D, respectively, the plurality of inner side insulating spacers 116 may be respectively formed on the plurality of side recesses R2. The plurality of inner side insulating spacers 116 may include silicon nitride.

Next, by performing similar processes to processes described above with reference to FIGS. 17 through 24, the integrated circuit device 100A illustrated in FIG. 26 may be formed.

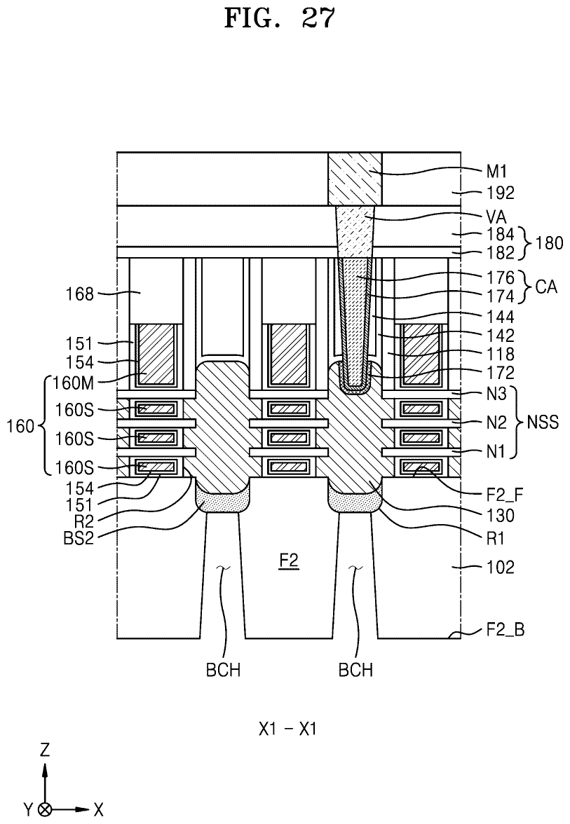

FIGS. 27 through 30 are cross-sectional views illustrating a method of manufacturing the integrated circuit device 200, according to embodiments. With reference to FIGS. 27 through 30, an example method of manufacturing the integrated circuit device 200 described above with reference to FIGS. 8 through 11, the same reference numerals as those in FIGS. 8 through 11 may represent the same members, and descriptions thereof are omitted herein.

FIGS. 27 through 30 are diagrams of a region taken along line X1-X1 in FIG. 8.

Referring to FIG. 27, on the resultant product formed by performing similar process to those described above with reference to FIGS. 11 through 24, by using a photo-lithography process, the substrate 102 may be polished from the backside surface F2_B of the substrate 102, and remove a portion of the plurality of active regions F2 to form a plurality of backside contact holes BCH. At least a portion of a bottom surface of the lower insulating spacer BS2 may be exposed from upper surfaces of the plurality of backside contact holes BCH.

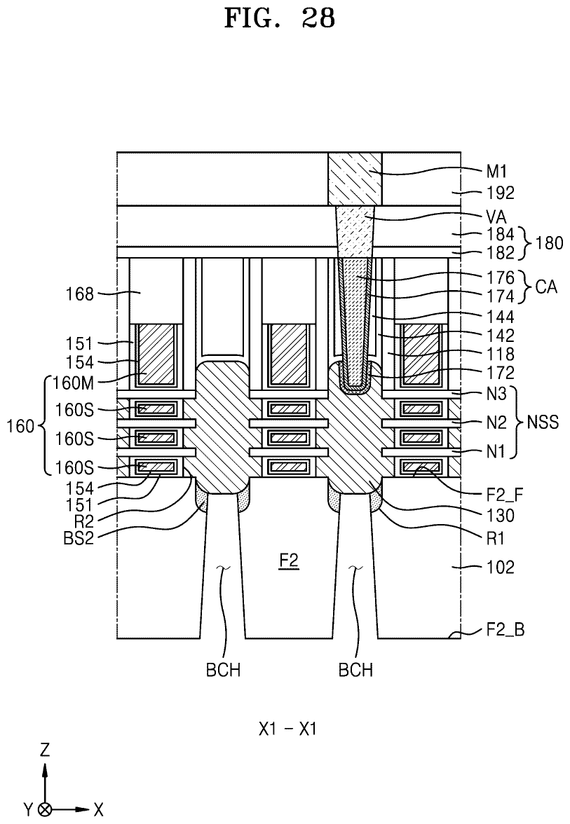

Referring to FIG. 28, by removing at least a portion of the exposed lower insulating spacer BS2 from the resultant product of FIG. 27, the plurality of backside contact holes BCH may extend to expose the source/drain region 130. A width of each of the plurality of backside contact holes BCH in the first horizontal direction (X direction) may be limited by two adjacent active regions F2 among the plurality of active regions F2, and a width of each of the plurality of backside contact holes BCH in the second horizontal direction (Y direction) may be limited by the device separation layer (refer to 112 in FIG. 10). In the first horizontal direction (X direction) and the second horizontal direction (Y direction), a width of each of the plurality of backside contact holes BCH may increase toward the backside surface F2_B of the active region F2.

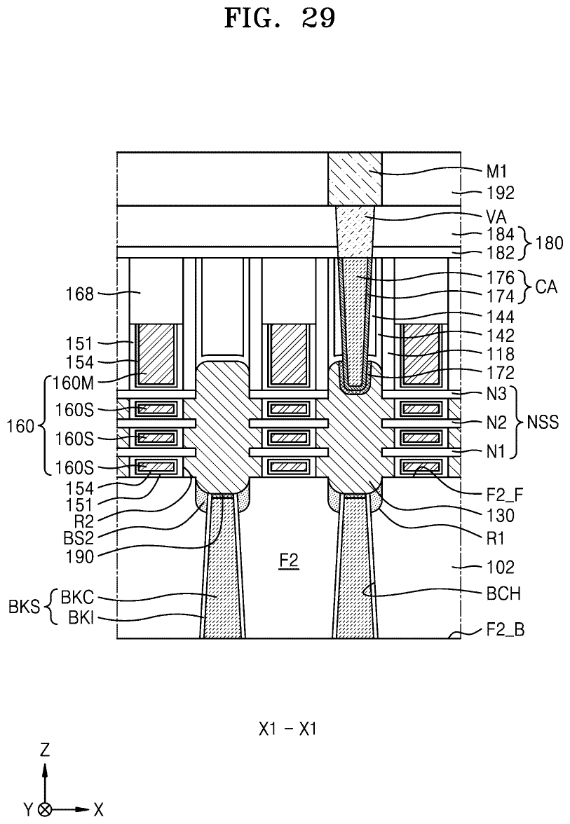

Referring to FIG. 29, the backside insulating spacer BK1 on and at least partially covering the surface of the active region F2 exposed on the internal sidewall of plurality of backside contact holes BCH may be formed, and by at least partially filling with a conductive material the plurality of backside contact holes BCH limited by each of the backside insulating spacer BK1 and the device separation layer (refer to 112 in FIG. 10), a plurality of backside contact structures BKS may be formed.

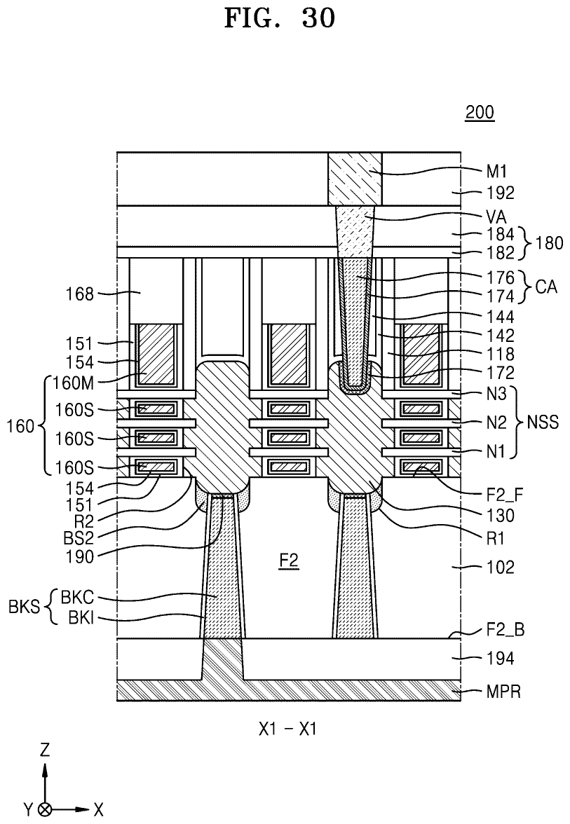

Referring to FIG. 30, the lower insulating layer 194 covering the lower surfaces of the plurality of backside contact structures BKS and a backside surface FB of each of the plurality of active regions F2, and the plurality of lower wiring structures MPR penetrating or extending through the lower insulating layer 194 in the vertical direction (Z direction) may be formed. The plurality of lower wiring structures MPR may include the lower wiring structure MPR connected to the backside contact BKC.

While embodiments of the inventive concept have been particularly shown and described with reference to embodiments thereof, it will be understood that various change in form and details may be made therein without departing from the spirit and scope of the following claims.

What is claimed is:

1. An integrated circuit device comprising:
an active region extending lengthwise in a first direction on a substrate;
a gate structure including a gate line, a high dielectric layer, and an interface dielectric layer, which extend lengthwise in a second direction perpendicular to the first direction on the active region;
a nanosheet arranged on a fin upper surface of the active region and contacting the gate structure;
a source/drain region arranged on the active region and contacting the nanosheet; and
under the source/drain region in a third direction perpendicular to both the first direction and the second direction, a lower insulating spacer arranged in a source/drain recess extending from the fin upper surface of the active region,
wherein the interface dielectric layer comprises:
a first portion extending on the nanosheet; and
a second portion extending on the source/drain region, and
wherein a first thickness of the first portion is different from a second thickness of the second portion.

2. The integrated circuit device of claim 1, wherein the source/drain region comprises a center portion and a protrusion portion extending from the center portion toward the gate structure.

3. The integrated circuit device of claim 2,
wherein the center portion comprises a first sidewall arranged on an identical flat surface to a sidewall of the nanosheet,
wherein the protrusion portion comprises a second sidewall arranged on an identical flat surface to a sidewall of the gate structure, and
wherein the first sidewall of the center portion and the second sidewall of the protrusion portion are arranged on different first surfaces.

4. The integrated circuit device of claim 1,
further comprising an inner side insulating spacer arranged between the source/drain region and the gate structure,
wherein the source/drain region is spaced apart from the gate structure with the inner side insulating spacer therebetween.

5. The integrated circuit device of claim 1, wherein the first thickness of the first portion of the interface dielectric layer is less than the second thickness of the second portion.

6. The integrated circuit device of claim 1, wherein the lower insulating spacer comprises a silicon nitride layer, a silicon oxide layer, or a combination thereof.

7. The integrated circuit device of claim 1, wherein the lower insulating spacer at least partially surrounds a bottom surface of the source/drain region.

8. The integrated circuit device of claim 1, wherein the lower insulating spacer overlaps only the active region in the first horizontal direction.

9. The integrated circuit device of claim 1, wherein the lower insulating spacer overlaps portions of the active region and the gate structure in the first direction.

10. The integrated circuit device of claim 1, wherein an uppermost end of the lower insulating spacer is identical to a level of the fin upper surface in the third direction, or is farther from the substrate than the fin upper surface.

11. An integrated circuit device comprising:
an active region extending lengthwise in a first direction on a substrate;
a gate structure including a gate line, a high dielectric layer, and an interface dielectric layer, which extend lengthwise in a second direction perpendicular to the first direction on the active region;
a nanosheet arranged on a frontside surface of the active region, and at least partially surrounded by the gate structure;
a source/drain region arranged on the active region and contacting the nanosheet;
a lower insulating spacer between the source/drain region and the substrate; and
a backside contact structure that extends through the active region and the lower insulating spacer from a backside surface facing the frontside surface of the active region, and is connected to the source/drain region,
wherein the interface dielectric layer comprises:
a first portion extending on the nanosheet; and
a second portion extending on the source/drain region, and
wherein a first thickness of the first portion is different from a second thickness of the second portion.

12. The integrated circuit device of claim 11,
wherein the lower insulating spacer is on a portion of sidewalls in the first direction, and
wherein the active region is on the other portion of the sidewalls of the backside contact structure in the first direction.

13. The integrated circuit device of claim 11,
wherein the backside contact structure comprises:
a backside contact; and
in the first direction, a backside insulating spacer arranged between the backside contact and the active region and between the backside contact and the lower insulating spacer.

14. The integrated circuit device of claim 13, further comprising a metal silicide layer arranged between the backside contact and the source/drain region.

15. The integrated circuit device of claim 11,
wherein the source/drain region comprises:
a center portion; and
a protrusion portion extending from the center portion toward the gate structure,
wherein sidewalls of the center portion and sidewalls of the protrusion portion are arranged on different flat surfaces.

16. The integrated circuit device of claim 11, wherein the lower insulating spacer comprises a silicon nitride layer.

17. The integrated circuit device of claim 11, wherein the lower insulating spacer and the backside contact structure at least partially surround a bottom surface of the source/drain region.

18. An integrated circuit device comprising:
a plurality of active regions extending lengthwise in a first direction on a substrate, and being spaced apart from each other in a second direction crossing the first direction;
a device separation layer on sidewalls of each of the plurality of active regions;
a gate structure including a gate line, a high dielectric layer, and an interface dielectric layer extending lengthwise in the second direction on the plurality of active regions;
a plurality of nanosheets arranged on a fin upper surface of each of the plurality of active regions, each of the plurality of nanosheets including at least one nanosheet, and the plurality of active regions at least partially surrounded by the gate line;
a source/drain region arranged on the plurality of source/drain regions, and arranged between the plurality of nanosheet stacks; and
under the source/drain region in a third direction perpendicular to both the first direction and the second direction, a lower insulating spacer arranged in a source/drain recess extending from the fin upper surface of the active region,
wherein the interface dielectric layer comprises:
a first portion extending on the nanosheet, and
a second portion extending on the source/drain region, and
wherein a first thickness of the first portion is less than a second thickness of the second portion.

19. The integrated circuit device of claim 18, wherein the integrated circuit device further comprises a backside contact structure that extends through the active region and the lower insulating spacer, and is connected to the source/drain region, and
wherein the lower insulating spacer and the backside contact structure at least partially surround a bottom surface of the source/drain region.

20. The integrated circuit device of claim 18,
wherein the lower insulating spacer surrounds a bottom surface of the source/drain region, and
the bottom surface of the source/drain region is spaced apart from the active region by the lower insulating spacer.
